(19) United States
(12) Patent Application Publication
(10) Pub. No.: US 2009/0314525 A1
(43) Pub. Date: Dec. 24, 2009

(54) Mold for Wiring Substrate Formation and Process for Producing the Same, Wiring Substrate and Process for Producing the Same, Process for Producing Multilayered Laminated Wiring Substrate and Method for Viahole Formation

(75) Inventors: Hitoshi Kajino, Saitama (JP); Takeo Taguchi, Saitama (JP); Kanji Sato, Saitama (JP); Masahito Ishii, Saitama (JP); Tatsuo Kataoka, Saitama (JP)

Correspondence Address: THE WEBB LAW FIRM, P.C., 700 KOPPERS BUILDING, 436 SEVENTH AVENUE, PITTSBURGH, PA, 15219, US

(73) Assignee: MITSUI MINING & SMELTING CO., LTD., Tokyo (JP)

(21) Appl. No.: 11/915,990

(22) PCT Filed: May 31, 2006
(86) PCT No.: PCT/JP2006/310933

§ 371 Date: Nov. 29, 2007

(30) Foreign Application Priority Data
Jun. 1, 2005 (JP) 2005-161617

(51) Int. Cl. H05K 1/03; H01K 3/22; H01R 43/16; H05K 3/10; H05K 1/11

(52) U.S. Cl. 174/255; 29/848; 29/874; 29/846; 174/261; 29/846; 174/256

(57) ABSTRACT

A process for producing a wiring board is provided, comprising allowing a wiring board-forming mold, which comprises a support base and a mold pattern that is formed in a protruded shape on one surface of the support base wherein the sectional width of the mold pattern on the support base side is larger than the sectional width thereof on the tip side in the same section of the mold pattern, to penetrate into a curing resin layer to transfer the mold pattern, curing the curing resin layer, releasing the laminate from the mold, depositing a conductive metal, and polishing the deposited metal layer that to form a depressed wiring pattern, and a wiring board produced by this process. Further, described is a process for producing a wiring board, comprising bringing a precision mold having a mold pattern on a surface of a mold base into contact with a surface of a metal thin film formed on an organic insulating base, pressing the mold to form a depression having a shape corresponding to the mold pattern of the precision mold in the organic insulating base, thereafter forming a metal plating layer having a thickness larger than the depth of the depression to fill the plating metal in the depression, and then polishing the metal plating layer until the organic insulating base is exposed, to form a wiring pattern, and a wiring pattern produced by this process.

### TECHNICAL FIELD

The present invention relates to a mold for forming wiring patterns of different depths in the thickness direction of an insulating resin substrate and a process for producing the mold. More particularly, the present invention relates to a process for producing a mold by selectively etching a metal layer formed on a surface of a support base, said mold being used for forming wiring patterns of different depths in the thickness direction of a curd body of a thermosetting or photo-curing resin, and also relates to the mold.

Further, the present invention relates to a wiring board in which wiring patterns of different depths in the thickness direction of an insulating resin substrate are formed, a process for producing the wiring board, a process for forming a via hole, and a process for producing a multi-layer laminated wiring board. More particularly, the present invention relates to a wiring board obtained by allowing a mold, which has a mold pattern formed by etching, to penetrate into a curing resin to form a depression and filling a conductive metal in the depression, a process for producing the wiring board, a process for producing a multi-layer laminated wiring board having the thus formed wiring pattern, and a process for forming a via hole that passes through an insulating layer.

Furthermore, the present invention relates to a process for producing a novel wiring board and a wiring board produced by the process. More particularly, the present invention relates to a process for producing a wiring board in which an extremely fine wiring pattern is embedded in an insulating base, and a wiring board produced by the process.

### BACKGROUND ART

As a method for mounting electronic components, a film carrier has been used. The film carrier hitherto used is formed by disposing a conductive metal such as copper on a surface of a polyimide film, coating a surface of a layer of the conductive metal with a photosensitive resin, exposing and developing the photosensitive resin to form a desired pattern and etching the metal layer using the thus formed pattern as a masking resist.

Such a film carrier has been extremely fined recently, and in order to form an extremely fine wiring pattern, the metal layer made of a conductive metal needs to be thinned. Since the thus formed ultrafine wiring pattern has a small line width and a small line thickness, the electrical resistivity given when an electric current flows tends to become large, and therefore, there occurs a problem that the quantity of heat generated by the film carrier itself due to Joule heat from the wiring pattern is increased. In order to inhibit heat generation of the film carrier, it is enough to increase the sectional area of the wiring pattern to be formed. In order to form the ultrafine wiring pattern, however, the thickness of the conductive metal layer for forming the wiring pattern needs to be decreased. Therefore, in the conventional process for producing a film carrier wherein a wiring pattern is formed by etching a metal layer that is formed on a surface of an insulating film using a conductive metal foil, there is limitation on the fining from the viewpoint of heat generation.

Aside from the fining of film carriers, in semiconductor packages that are frontier electronic components, buildup wiring boards wherein plural conductor layers and insulating layers are laminated to secure electrical connection in the thickness direction have been widely employed. As methods to secure electrical connection among the laminated layers in such buildup wiring boards, there have been adopted a method wherein a via hole is formed in the laminated insulating layers and a plating layer is formed in the via hole to secure electrical connection in the thickness direction, a method wherein a via hole is filled with a conductive paste to secure electrical connection in the thickness direction, a method wherein a silver bump thrusting through an insulating layer is formed to secure electrical connection in the thickness direction, a method wherein electrical connection in the thickness direction is secured by means of a via post, etc. (see non-patent document 1: Journal of Japan Institute of Electronics Packaging, Vol. 2, No. 6, pp. 450-453 (1999); non-patent document 2: Journal of Japan Institute of Electronics Packaging, Vol. 2, No. 1, pp. 6-8 (1999)).

In the above methods, however, the step of forming a wiring pattern and the step of securing electrical connection in the thickness direction of the wiring board are completely different steps, and an extremely complicated process is required to produce a buildup wiring board. Moreover, connection failures frequently occur among the thus formed layers, and therefore, a reliable and simple method to secure interlayer connection has been desired. Further, with promotion of fining and densification of wiring patterns, the region for forming via holes has been restricted, and the area required for forming the via hole that secures electrical connection in the thickness direction is decreased. In the conventional method to secure electrical connection in the thickness direction by forming a plating layer on the inside wall surface of the via hole, the area occupied by the via hole and its surrounding land is large, and therefore, such a conventional method can hardly cope with the recent fining and densification of wiring patterns. In the conventional method to secure electrical connection in the thickness direction by means of via holes or bumps, it is difficult to form via holes in such a manner that they lie one upon another at the same positions in the thickness direction of the laminated wiring boards (it is difficult to form stack-up via holes). Therefore, the via holes are formed in the respective layers by shifting their positions in the thickness direction (sequential buildup) in many cases, and the degree of freedom in designing of semiconductor packages is sometimes restricted.

By the way, a process for producing resist patterns, which is called “imprinting method”, has been proposed recently (see, for example, S. Y. Chou, et al., Appl. Phys. Lett., Vol. 167, p. 3314 (1995) (non-patent document 3)). In the process for producing patterns by the imprinting method, a silicon substrate is first etched by electron beam lithography or the like to form a mold having a depression and a protrusion on its surface, then the substrate is coated with a resin film such as a PMMA film, the resin film is heated to a temperature of not lower than the softening point together with the substrate, then the mold is pressed onto the softened resin film to transfer the depression and the protrusion to the resin film, and the resin film is cooled to a temperature of not higher than the softening point to fix the depression and the protrusion that have been transferred to the resin film. Subsequently, the mold is removed from the resin film surface, and of the resin film having the depression and the protrusion, a residual film remaining on the bottom of the depression is removed by an anisotropic plasma etching method such as reactive ion etching (RIE). That is to say, the imprinting method is a method for forming a resist pattern using a resin film having a depression and a protrusion that have been transferred from a surface of a silicon substrate.

In the above imprinting method, it is necessary to heat a resin, which is used for transferring a protrusion and a depression formed on a silicon substrate, to a temperature of not lower than the softening point of the resin and to cool the resin to a temperature of not higher than the softening point after the depression and the protrusion are transferred, so that there is a problem of a prolonged processing time.

Further, the mold used for the imprinting method is formed by, for example, etching a silicon substrate by electron beam lithography or the like, and therefore, there is a problem that when a resin film having the transferred depression and protrusion is released from the mold, a part of the resin film sometimes remains in the mold.

As a means to solve the above problems, it is disclosed in a patent document 1 (Japanese Patent Laid-Open Publication No: 304097/2004) to use a photo-curing resin instead of the thermosetting resin such as PMMA and to use a mold substrate having light transmission properties for the mold in the imprinting method. Since the photo-curing resin is used, the resin is cured by photo-curing reaction, that is, curing of the resin is carried out without performing the steps of heating and cooling. Therefore, the production process can be simplified.

In the above process, however, the mold is provided with a depression and a protrusion by etching the silicon substrate surface through electron beam lithography or the like, and therefore, there resides a problem that when the mold is released from the photo-curing resin having the transferred depression and protrusion, a cured resin is liable to remain in the mold.

Also in a patent document 2 (Japanese Patent Laid-Open Publication No. 194142/2000), use of a photo-curing resin instead of a thermosetting resin is disclosed, but there is the same problem as above.

In a patent document 3 (Japanese Patent Laid-Open Publication No. 77807/2003), there is disclosed a mold including a mold main body having a pressing surface provided with a protrusion or a depression for forming a pattern and a surface-treated layer having been subjected to hydrophobic treatment through plasma treatment using a gas containing fluorine atoms. By the surface treatment utilizing plasma treatment using a gas containing fluorine atoms, improvement in demolding can be expected to some extent, but in the mold, the protrusion or the depression is formed at substantially right angles to the substrate. Therefore, even if the surface profile of the protrusion or the depression of the mold is improved, there still resides a problem that the protrusion or the depression tends to have defects when the mold is released from a resin cured body formed by introducing a resin into the protrusion or the depression of the mold.

As described above, downsizing of electronic products is further promoted recently, and in order to form wiring patterns of fine pitch, subtractive process is considered to be suitable.

However, even if a wiring pattern of ultrafine pitch is produced by the subtractive process that is considered to be suitable for forming wiring patterns of fine pitch, solder runs on the bottom of the wiring pattern (bottom of wiring pattern on insulating substrate side) in the soldering step to sometimes cause short circuit between the neighboring wiring patterns, because the wiring pattern is formed in a protruded shape from the surface of the insulating substrate.

Especially in the recent ultrafine wiring patterns, a risk of occurrence of short circuit due to running of solder is considered to become high.

In order to prevent formation of a bridge due to solder joint, there is a method of filling up the space between the wiring patterns with a solder resist. In this method, however, wiring patterns of ultrafine pitch need extremely high printing alignment accuracy. Moreover, however accurately the coating operation may be carried out, it is almost impossible to allow the actually coated portion and the coating intended portion to completely coincide with each other because the solder resist runs out.

Use of a photoresist instead of the above solder resist can be considered, but also in this method, there is limitation on the alignment accuracy of a photomask, so that this method is insufficient to produce a wiring pattern of ultrafine pitch.

Aside from the above problem of alignment accuracy, chip size packages (CSP) using solder balls as outer terminals of wiring patterns have been frequently used. However, the CSP produced by the conventional subtractive process or the like has a problem that the areas of pads including shoulders tend to become non-uniform and the heights of the molten solder balls are not equal to one another. In the case of such CSP, further, when solder balls are arranged on pads in holes formed in an insulating film such as a polyimide film and soldered thereto, vacancies tend to be formed at the corners of the pad bottoms, and reliability about the electrical connection using solder balls sometimes becomes a problem.

In Japanese Patent Laid-Open Publication No. 218500/2003 (patent document 4), there is disclosed a process for producing an embedded conductor pattern film, comprising processing a conductive metal foil laminated on a support to form a wiring pattern, embedding the thus formed wiring pattern in a thermoplastic resin and then peeling the support to give a thermoplastic resin film in which the wiring pattern is embedded.

In this process, however, the conductor pattern embedded in the thermoplastic resin is formed by etching a conductive metal such as a copper foil using photolithography, and therefore, this process is not suitable for producing a wiring board having a wiring pattern of ultrafine pitch.

Patent document 1: Japanese Patent Laid-Open Publication No. 304097/2004

Patent document 2: Japanese Patent Laid-Open Publication No. 194142/2000

Patent document 3: Japanese Patent Laid-Open Publication No. 77807/2003

Patent document 4: Japanese Patent Laid-Open Publication No. 218500/2003

Non-patent document 1: Journal of Japan Institute of Electronics Packaging, Vol. 2, No. 6, pp. 450-453 (1999), “Technique and Characteristics of Buildup Wiring Boards”

Non-patent document 2: Journal of Japan Institute of Electronics Packaging, Vol. 2, No. 1, pp. 6-8 (1999), “Trend and Future of Buildup Technology”

Non-patent document 3: S. Y. Chou, et al., Appl. Phys. Lett., Vol. 167, p. 3314 (1995)

### DISCLOSURE OF THE INVENTION

### Problem to be Solved by the Invention

It is an object of the present invention to provide a mold that is used for forming a wiring pattern by a so-called imprinting method and a process for producing the mold.

It is an object of the present invention to provide a process for producing a wiring board using a novel mold for imprinting, and a novel wiring board produced by the process.

It is a further object of the present invention to provide a process for forming a via hole using the above mold, said via hole making electrical connection between a front and a back surfaces of a wiring board.

It is a further object of the present invention to provide a process for producing a multi-layer wiring board in which the wiring boards produced as above are laminated in a multi-layer form.

It is a further object of the present invention to provide a novel process for producing a wiring board in which an ultrafine wiring pattern is embedded in an insulator.

It is a further object of the present invention to provide a novel wiring board produced by the above process for producing a wiring board.

### Means to Solve the Problem

The wiring board-forming mold of the present invention is a wiring board-forming mold comprising a support base and a mold pattern that is formed in a protruded shape on one surface of the support base, wherein the sectional width of the mold pattern on the support base side is larger than the sectional width thereof on the tip side in the same section of the mold pattern.

In the wiring board-forming mold of the present invention, the support base can be a light-transmitting base.

Moreover, the wiring board-forming mold of the present invention is a wiring board-forming mold for forming a pattern in a photo-curing or thermosetting resin layer, which comprises a support base and a mold pattern and in which at least two mold patterns having different heights are formed, and a difference between the height of the highest mold pattern among the mold patterns and the thickness of the resin layer into which said highest mold pattern is allowed to penetrate is in the range of 0.1 to 3 μm. That is to say, the highest mold pattern is formed so that the height thereof should be lower by 0.1 to 3 μm than the thickness of the resin layer.

In addition, the process for producing a wiring board-forming mold of the present invention comprises carrying out, at least once, a selective etching step which comprises forming a photosensitive resin layer on a surface of a metal layer formed on one surface of a support base, exposing and developing the photosensitive resin layer to form a pattern made of the photosensitive resin cured body and selectively etching the metal layer using the pattern as an etching resist, to form a pattern made of the metal on the surface of the support base.

In the wiring board-forming mold of the present invention, the mold pattern is formed by etching the metal layer with an etching solution as above. Therefore, the sectional shape of the mold pattern is a trapezoid wherein the bottom base width on the support base side is larger than the top base width, so that demolding is readily made and a wiring board rarely suffering defects can be produced.

The wiring board of the present invention is a wiring board comprising an insulating layer having a depression on its surface and a conductive metal filled in the depression, wherein a wiring pattern is formed from the conductive metal filled in the depression and is formed in such a manner that the sectional width of the depressed wiring pattern is decreased in the depth direction from the surface of the insulating layer.

The wiring board of the present invention can be produced by a process comprising:

allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into an uncured or semi-cured curing resin layer of a laminate having the curing resin layer on a surface of a support, to transfer the mold pattern,

curing the curing resin layer,

then releasing the laminate from the mold,

depositing a conductive metal on the surface of the thus released laminate, and

then polishing the deposited metal layer in such a manner that the surface of the cured resin layer of the laminate is exposed, to form a depressed wiring pattern.

The process for forming a via hole of the present invention comprises:

allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into an uncured or semi-cured curing resin layer of a laminate having the curing resin layer on a surface of a support, to transfer the mold pattern,

curing the curing resin layer,

then releasing the laminate from the mold,

depositing a conductive metal on the surface of the thus released laminate, and

then polishing the deposited metal layer in such a manner that the surface of the cured resin layer of the laminate is exposed, to form a via hole that passes through the cured resin layer of the laminate.

The process for producing a multi-layer laminated wiring board of the present invention comprises carrying out, at least once, a step which comprises:

allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into an uncured or semi-cured curing resin layer of a laminate having the curing resin layer on a surface of a support comprising a conductive metal, to transfer the mold pattern,

curing the curing resin layer,

then releasing the laminate from the mold,

then preferably, removing smears from the bottom surface of the depression,

depositing a conductive metal on the surface of the released laminate,

then polishing the deposited metal layer in such a manner that the surface of the cured resin layer of the laminate is exposed, to form a depressed wiring pattern and a via hole that passes through the cured resin layer of the laminate, and further comprising, at least once,

forming an uncured or semi-cured curing resin layer on the cured resin surface on which the depressed wiring pattern and the via hole have been formed,

allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into the curing resin layer, to transfer the mold pattern,

curing the curing resin layer,

then releasing the curing resin cured body from the mold,

then preferably, removing smears from the bottom surface of the depression,

depositing a conductive metal on the surface of the released cured resin layer laminate, and

then polishing the deposited metal layer in such a manner that the surface of the curing resin cured body layer of the laminate is exposed, to form a depressed wiring pattern and a via hole that passes through the cured resin layer of the laminate.

In the present invention, by the use of a mold having a mold pattern formed by etching a metal layer, a depression is formed in an uncured or semi-cured curing resin layer, and this depression is filled with a conductive metal to form a depressed wiring pattern in the curing resin cured body, so that the depressed wiring pattern is formed in such a manner that the sectional width of the depressed wiring pattern is decreased in the depth direction from the surface of the insulating layer. The wiring board of the present invention can have plural depressed wiring patterns of different depths, and among the depressed wiring patterns of different depths, the deepest depressed wiring pattern may pass through the curing resin cured body that is an insulating layer to reach the back surface side this depressed wiring pattern reaching the back surface side of the insulating layer is a via hole to secure electrical connection between the front and the back surfaces of the wiring pattern.

According to the process for producing a wiring board of the present invention, a depressed wiring pattern is formed in the insulating layer, and at the same time, a via hole can be formed in the insulating layer.

In the mold for use in the present invention, the mold pattern is formed by etching a metal layer, and the sectional shape of the mold pattern is a trapezoid wherein the bottom base width on the support base side is larger than the top base width, so that demolding is readily made and a wiring board rarely suffering defects can be produced.

The process for producing a wiring board of the present invention comprises bringing a precision mold having a mold pattern formed on a surface of a mold base into contact with a surface of a metal thin film formed on an organic insulating base, pressing the mold to form a depression having a shape corresponding to the mold pattern formed in the precision mold, said depression being formed in the depth direction of the organic insulating base from the metal thin film side, thereafter forming a metal plating layer having a thickness larger than the depth of the depression formed on the metal thin film to fill the plating metal in the depression formed by the precision mold, and then polishing the metal plating layer until the organic insulating base is exposed from the surface of the metal plating layer, to form a wiring pattern.

Moreover, the wiring board of the present invention comprises a wiring pattern that is formed by filling a plating metal, through a metal thin film, in a depression formed in an organic insulating base.

On the surface of the wiring pattern, a plating layer of a metal that is different from the metal filled in the depression is preferably formed.

### EFFECT OF THE INVENTION

In the mold of the present invention, a desired mold pattern is formed by forming a photosensitive resin layer on a surface of a metal layer formed on a surface of a support baser then exposing and developing the photosensitive resin layer to form a desired pattern and etching the metal layer using the thus formed pattern as an etching resist. When the section of the thus formed mold pattern is observed, the sectional width of the bottom of the mold pattern on the support base side is larger than the sectional width of the top thereof.

Therefore, by pressing the mold into an uncured or semi-cured curing resin and then applying light and/or heat to the uncured or semi-cured resin introduced between the patterns formed in the mold of the present invention, the resin can be cured. In the mold pattern formed in the mold, the sectional width of the tip (top) is narrower than the sectional width of the lower end on the support base side, so that the mold of the present invention can be readily released from the cured resin after curing, and adhesion of the cured resin or the like onto the surface of the mold does not take place.

In the mold of the present invention, mold patterns of different heights can be formed by performing multistage etching of a metal layer formed on the surface of the support base, and if a curing resin layer having a thickness almost equal to the height of the highest mold pattern is formed, a depression formed by this highest mold pattern can be used as a through hole for forming a via hole in an insulating layer made of a resin cured body (film, sheet or board).

The line width of the depressed wiring pattern formed by the use of the mold of the present invention is usually not more than 10 μm, and by further enhancing exposing/developing accuracy, a wiring pattern having a line width of nanometer size can be formed. Even if the line width is narrowed as above, the depressed wiring pattern formed by the use of the mold of the present invention can be ensured to have a sectional area of a certain value or more by forming the depressed wiring pattern deeply in the thickness direction of the resin cured body (insulating layer). Consequently, by the use of the mold of the present invention, the electrical resistivity of the depressed wiring pattern formed does not become markedly high, and therefore, overheat of the wiring board due to Joule heat generated during the electrical conduction can be prevented.

In the wiring board of the present invention, a depressed wiring pattern is formed in the depth direction in the insulating layer that is formed by curing a curing resin layer. This depressed wiring pattern can be formed by transferring a mold pattern onto the curing resin layer using a mold having a desired mold pattern, said mold pattern being formed by forming a photosensitive resin layer on a surface of a metal layer formed on a surface of a support baser then exposing and developing the photosensitive resin layer to form a desired pattern and etching the metal layer using the thus formed pattern as a masking material.

That is to say, in the mold for use in the present invention, a desired mold pattern is formed by forming a photosensitive resin layer on a surface of a metal layer formed on a surface of a support base, then exposing and developing the photosensitive resin layer to form a desired pattern and etching the metal layer using the thus formed pattern as a masking material. When the section of the thus formed mold pattern is observed, the sectional shape of the mold pattern is a trapezoid wherein the bottom base width on the support base side is larger than the top base width. By allowing the mold pattern formed in the mold to penetrate into the curing resin layer, then curing the curing resin layer and releasing the curing resin cured body from the mold, a depression for forming a depressed wiring pattern can be formed in the curing resin cured body (insulating layer). As described above, the shape of the mold pattern to form a depression in the insulating layer is substantially a trapezoid, so that demolding can be easily made, and flaw of the curing resin cured body (insulating layer) hardly takes place. In particular, even if a depression of a small line width and a large depth is formed, demolding is readily made and defects hardly occur. According to the present invention, therefore, a wiring in which the wiring width is narrowed in order to increase wiring density and the wiring depth is increased in order to lower sheet resistivity can be readily formed.

The line width of the depressed wiring pattern in the wiring board of the present invention is usually not more than 10 μm, and by further enhancing exposing/developing accuracy, a depressed wiring pattern having a line width of nanometer size can be formed. Even if the line width is narrowed as above, the depressed wiring pattern formed in the wiring board can be ensured to have a sectional area of a certain value or more by forming the depressed wiring pattern deeply in the thickness direction of the resin cured body. Consequently, the electrical resistivity of the depressed wiring pattern formed in the wiring board of the present invention does not become markedly high, and therefore, overheat of the wiring board due to Joule heat generated when electricity passes through the depressed wiring pattern can be prevented.

By repeating, e.g., half etching in the formation of a mold pattern of a mold, patterns of different heights can be formed, and by the use of such mold patterns, depressions having different depths can be formed at the same time.

By the use of a through hole formed by the highest mold pattern formed in the mold and passing through the curing resin cured body (insulating layer), a via hole can be formed. In the present invention, formation of a via hole and formation of a wiring pattern can be carried out at the same time.

If an operation of transferring a desired pattern to the curing resin layer using the above mold to form a depressed wiring pattern is repeated, a multi-layer laminated wiring board wherein plural wiring boards are laminated can be produced. In such a multi-layer laminated wiring board, positions of via holes to secure electrical connection between the laminated wiring boards can be freely selected. Moreover, electrical connection between the laminated wiring boards can be surely secured, and the area occupied by the via holes for making electrical connection between the laminated boards is small.

In the process for producing a wiring board of the present invention, by the use of a precision mold (mold press) having a protruded pattern reverse to a wiring pattern, a groove of a wiring circuit is formed in an organic insulating base on a surface of which an extremely thin metal film of excellent extensibility has been formed, thereafter the precision mold is pulled up, then a metal is deposited inside the groove by electroplating to fill up the depression with the metal, and the resulting electroplating layer is polished until the resin layer of the organic insulating base is exposed from the electroplating layer, whereby a wiring pattern is formed. Accordingly, the wiring pattern is embedded in the organic insulating base and is substantially flush with the surface of the organic insulating base. Since the wiring pattern does not substantially protrude from the surface of the organic insulating base as described above, a solder bridge between wiring patterns does not occur even if the pitch width between the wiring patterns is narrow. Further, since the wiring pattern is formed by polishing the plating layer, the surface can be made uniform. Furthermore, the wiring pattern is formed so as to be substantially flush with the organic insulating base, and therefore, even if a solder ball is arranged on the wiring pattern, there is no corner portion at the pad bottom, so that any vacancy is not formed. Consequently, reliability about the connection using a solder ball can be extremely enhanced.

### BRIEF DESCRIPTION OF THE DRAWINGS

FIG. 1 is a sectional view schematically showing an embodiment of a wiring board-forming mold of the present invention and an embodiment of a substrate processed using the mold.

FIG. 2 is a group of sectional views schematically showing an embodiment of a process for producing a wiring board-forming mold of the present invention.

FIG. 3 is a group of sectional views schematically showing an embodiment of a process for producing a wiring pattern using a wiring board-forming mold of the present invention.

FIG. 4 is a group of sectional views schematically showing an embodiment of a process for producing a double-sided printed wiring board using a wiring board-forming mold of the present invention.

FIG. 5 is a group of sectional views schematically showing an embodiment of a process for producing a buildup wiring board using a wiring board-forming mold of the present invention.

FIG. 6 is a group of sectional views each of which shows an embodiment of a substrate in each step for producing a via hole using a mold.

FIG. 7 is a group of views showing another embodiment of a process for producing a wiring board-forming mold of the present invention.

FIG. 8 is a group of views showing another embodiment of a process for producing a wiring board-forming mold of the present invention.

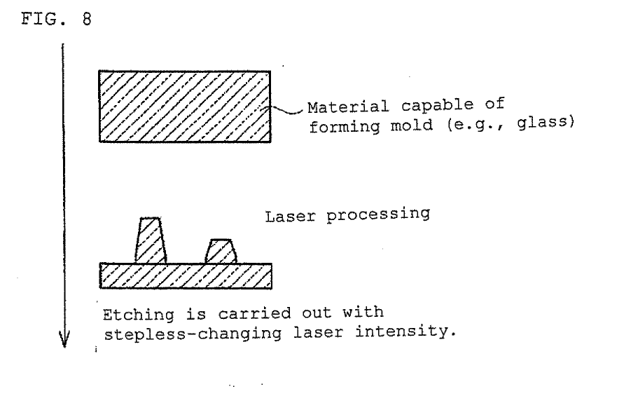

FIG. 9 is a group of views each of which schematically shows a section of a substrate in each step for producing a wiring board of the present invention.

FIG. 10 is a group of views each of which schematically shows a section of a substrate in each step for producing a wiring board of the present invention.

FIG. 11 is a view schematically showing a section of a precision mold used in the present invention.

### DESCRIPTION OF SYMBOLS

10: wiring board-forming mold
11: hard metal layer
12: support base
13: photosensitive resin layer
13a, 13b, 13c, 13d: pattern (masking material)
14a, 14b, 14c: mold pattern
14a-t, 14b-t, 14c-t: top of mold pattern
14a-b, 14b-b, 14c-b: bottom of mold pattern
16: mask
24a, 24b, 24c, 24d, 24e, 24f, 24g: gap
25: residual layer
30: laminate
32: support
32a, 32b, 32c, 32d: depressed wiring pattern
33: uncured curing resin layer
34: cured body layer (insulating layer) (photosensitive resin)
34a: insulating layer
41: deposited metal (layer)
45: conductive metal
45a, 45b, 45c: conductive metal
46a, 46b, 46c: depressed wiring pattern
55d, 55e, 55f, 55g: protruded wiring pattern
Tal: height of mold pattern 14a
Rd: thickness of curing resin layer
Bt: thickness difference
110: organic insulating base
111: support
112: metal thin film
120: depression
122: metal plating layer
124: plating metal
126: wiring pattern
127: upper end
128: plating layer
129: electroless tin plating layer
130: precision mold
131: mold base
133: mold pattern
135: polishing means

### BEST MODE FOR CARRYING OUT THE INVENTION

Next, the wiring board-forming mold of the present invention, the process for producing the mold, the wiring board produced by the use of the mold, the process for producing the wiring board, and the process for forming a via hole are described in detail. Further, the process for producing a novel wiring board of the present invention and the wiring board obtained by the process are also described in detail.

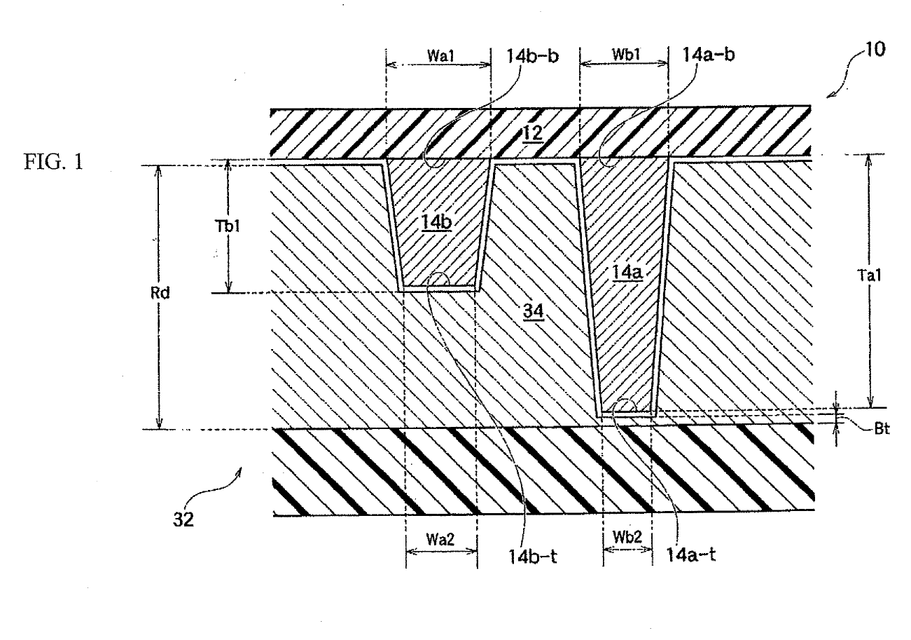

In FIG. 1, an embodiment of the wiring board-forming mold of the present invention and an embodiment of a substrate processed using the mold are schematically shown.

Referring to FIG. 1, the wiring board-forming mold of the present invention is designated by numeral 10. The wiring board-forming mold 10 of the present invention has a support base 12 and mold patterns 14a and 14b formed on one surface of the support base 12.

The support base 12 to constitute the wiring board-forming mold 10 of the present invention holds mold patterns 14a and 14b and can be formed from a metal, a glass, a resin or the like. When an insulating layer of a wiring board is formed from a cured body of a photosensitive resin, the support base 12 is preferably a light-transmitting base. The light-transmitting base 12 may be one that transmits light for curing a photosensitive resin 34. For curing a photo-curing resin, various lights, such as electron rays, ultraviolet light, visible light and infrared light, are employable, and it is preferable to use light of relatively short wavelength such as visible light or ultraviolet light.

When the insulating layer to constitute a wiring board is a cured body of a thermosetting resin, the support base 12 to constitute the wiring board-forming mold 10 of the present invention can be formed from a metal, a synthetic resin, a glass or a plate of a combination of these materials.

When the insulating layer to constitute a wiring board is a cured body of a photosensitive resin, the support base 12 to constitute the wiring board-forming mold 10 of the present invention transmits light for curing the photosensitive resin 34, and for the support base 12, quartz, a quartz glass, a glass, a transparent synthetic resin or a plate of a combination of these materials is used. Especially, when the insulating layer is a cured body of a photosensitive resin, visible light or ultraviolet light having short wavelength is desirably used in the present invention, and for the light-transmitting base 12, quartz, a quartz glass, Pyrex (trade name) or the like having properties of transmitting these rays are preferably used. When a light-transmitting resin is used for the light-transmitting base 12, acrylic resin, polyethylene terephthalate, polyethylene naphthalate, polycarbonate, polymethyl methacrylate, etc. having excellent transmission properties to these rays are employable. As the light-transmitting resin, a resin stable to an etching solution is desirably used because the mold pattern is formed by etching. The photo-curing resin 34 is cured by photopolymerization. In order that the resin is completely cured by photopolymerization, the light irradiation time needs to be markedly prolonged, and in a usual case, after the photo-curing resin 34 is cured to such an extent that the shape given by the wiring board-forming mold can be held, thermal curing is preferably carried out to complete the curing reaction. When thermal curing is carried out, a resin capable of standing a heating temperature for the thermal curing, e.g., a resin having a softening temperature of not lower than 120° C., is preferably used. Therefore, if a light-transmitting resin is used, polycarbonate is preferably used in the present invention.

Such a support base 12 does not particularly need to have flexibility. The support base 12 desirably has a certain thickness because a certain pressure is applied thereto in the mold pressing, and the thickness of the support base 12 is in the range of usually 0.3 to 50 mm, preferably 0.5 to 20 mm.

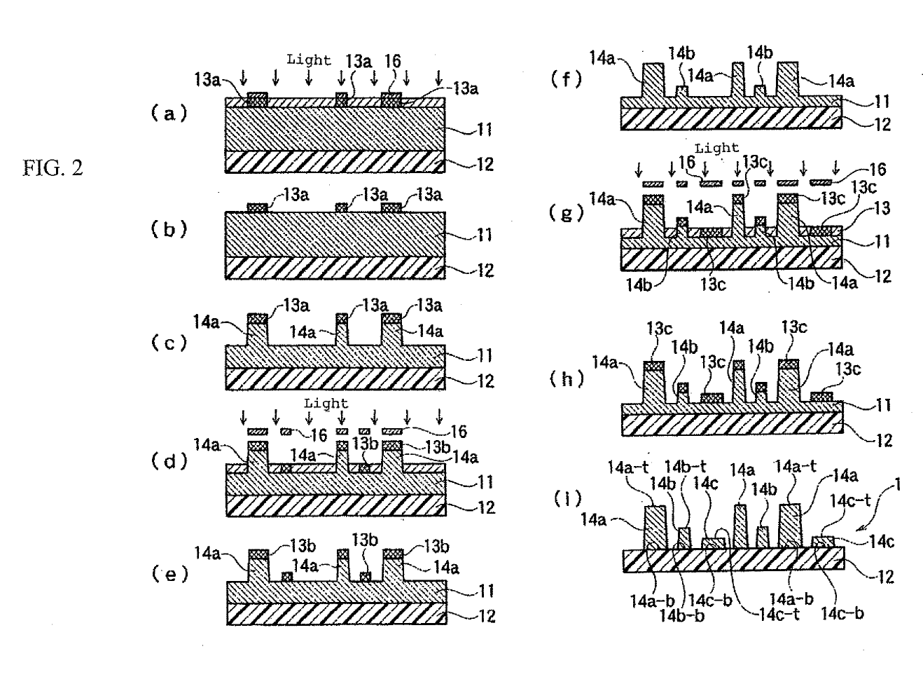

On the surface of the support base 12, mold patterns 14a, 14b, 14c, - - - are formed. As shown in FIG. 1 and FIG. 2(i), plural mold patterns 14a, 14b and 14c - - - of different heights are formed in the wiring board-forming mold 10 of the present invention. As shown in FIG. 1 and FIG. 2(i), the sectional width Wa2 or Wb2 of the mold pattern at the top 14a-t or 14b-t of the mold patterns 14a, 14b, 14c, - - - formed in the wiring board-forming mold 10 of the present invention is different from the sectional width Wa1 or Wb1 of the bottom 14a-b or 14b-b on the side of the support base 12 of the mold patterns 14a, 14b, 14c, - - - . For example, in comparison between the sectional width Wa1 of the bottom 14a-b and the sectional width Wa2 of the top 14a-t, the sectional width Wa2 of the top 14a-t is apparently narrower than the sectional width Wa1 of the bottom 14a-b. By making the sectional width of the top of the mold pattern narrower than the sectional width of the bottom, the wiring board-forming mold 10 of the present invention can be favorably released after the curing resin designated by numeral 34 is cured. Especially when the ratio (W1/W2) of the sectional width of the bottom to the sectional width of the top, specifically, Wa1/Wa2 or Wb1/Wb2, is in the range of usually 1.01 to 2.0, preferably 1.1 to 1.5, the mold can be easily released. If the W1/W2 value is less than the lower limit of the above range, mold releasability is deteriorated, and if the W1/W2 value exceeds the upper limit of the above range, formation of fine circuit becomes difficult. By allowing the mold pattern to have a slope as above, the slope face of the mold pattern is also exposed to light from the light-transmitting base side, and therefore, if the curing resin is a photo-curing resin, this side face portion is also photo-cured. Consequently, the shape of the pattern formed from the photo-curing resin is hardly broken when the mold is released, and besides, because the photo-curing reaction of the side face portion is accelerated, adhesion of the curing resin to the mold pattern can be effectively prevented.

In the wiring board-forming mold 10 of the present invention, plural mold patterns of different heights are formed. FIG. 1 shows an embodiment in which a mold pattern 14a having a height Ta1 almost equal to a thickness Rd of a curing resin layer 34 and a mold pattern 14b having a height Tb1 that is about ½ of the height Ta1 are formed. FIG. 2(i) shows an embodiment in which a mold pattern 14c having a height that is about a half of the height of the mold pattern 14b is formed in addition to the mold pattern 14a and the mold pattern 14b. Although the height Ta1 of the highest mold pattern 14a may be the same as the thickness (or height) Td of the curing resin layer, it is preferable that the thickness of the curing resin layer 34 is larger by a thickness Bt, as shown in FIG. 1, because wear of a tip of the metal mold pattern 14a is liable to occur when the tip of the mold pattern 14a is brought into direct contact with a support 32 on which the curing resin layer 34 is formed. The thickness Bt is usually in the range of about 0.01 to 3 μm.

The wiring board-forming mold 10 of the present invention can be produced by forming a hard metal layer 11 on a surface of the support base 12 and selectively etching the hard metal layer 11.

FIGS. 2(a) to 2(i) are explained below. The metal layer 11 is formed on a surface of the light-transmitting base 12 such as a glass base, then a photosensitive resin layer 13 is formed on the surface of the metal layer 11, and on the surface of the photosensitive resin layer 13, a mask 16 of a desired pattern is placed (FIG. 2(a)), and the photosensitive resin layer 13 is irradiated with light from the mask 16 side to perform light exposure and developed to form a pattern 13a (FIG. 2(b)). Examples of metals used to form the metal layer 11 include nickel, nickel alloy, cobalt, cobalt alloy, copper, copper alloy and alloys thereof. Because the mold is repeatedly used, the metal is desirably hard so as not to be worn by the use of the mold, and because precision etching is carried out using a proper etching solution and a proper etching method, the metal preferably has excellent etchability. In the present invention, copper and nickel having excellent etchability are particularly preferable. According to circumstances, the metal layer may be plated with a hard metal such as chromium.

By the use of a metal having excellent etchability as above, mold patterns (top sectional width) ranging from a relatively rough pattern having a top maximum sectional width of, for example, not more than 650000 nm, preferably not more than 35000 nm, more preferably not more than 10000 nm, to a relatively fine pattern having a top minimum sectional width of, for example, not less than 10 nm, preferably not less than 100 nm, more preferably not less than 1000 nm, can be formed though it depends upon the wavelength of light or electron beam used in the lithography.

The wiring board-forming mold 10 of the present invention can be produced by, for example, a process shown in FIG. 2.

FIG. 2 is a group of sectional views each of which schematically shows a section of a mold in each step in an embodiment of the process for producing a wiring board-forming mold of the present invention including etching steps of three times.

In the process for producing the wiring board-forming mold 10 of the present invention, a metal layer 11 is formed on one surface of a support base 12, as shown in FIG. 2(a) The metal layer 11 can be formed by depositing the aforesaid metal on the surface of the support base 12 through electroless plating, electroplating, laminating, sputtering or the like. The plating method is preferable because a metal layer of high hardness tends to be obtained. Although the thickness of the metal layer 11 can be properly selected according to the depth of a wiring pattern to be formed, it is usually not more than 65 μm, preferably not more than 50 μm, more preferably not more than 40 μm. Although the lower limit of the thickness is not particularly restricted, the lower limit is usually 1 μm or more, preferably 5 μm or more, particularly preferably 10 μm or more, taking production stability into account.

On the surface of the metal layer 11 formed as above, a photosensitive resin layer 13 is formed, then a mask 16 of a desired shape is placed on the surface of the photosensitive resin layer 13, and the photosensitive resin layer 13 is irradiated with light through the mask 16 to perform light exposure. As the photosensitive resin to form the photosensitive resin layer 13, there is a resin of such a type that when the resin is irradiated with light, the irradiated portion is cured, or a resin of such a type that when the resin is applied, a cured body is formed, but when the cured body is irradiated with light, the irradiated portion is softened and melted. In the present invention, any of these types is employable. FIG. 2 shows the latter case.

Referring to FIGS. 2(a) and 2(b), the pattern obtained by the light exposure and development using the mask 16 is designated by numeral 13a. That is to say, the photosensitive resin layer 13 is formed on the surface of the metal layer 11, then the mask 16 is placed on the surface of the photosensitive resin layer 13, and the photosensitive resin layer 13 is exposed to light and developed, as shown in FIG. 2(a), whereby a cured body 13a of the photosensitive resin corresponding to the mask 16 remains on the surface of the metal layer 11, as shown in FIG. 2(b).

In the present invention, using the cured body 13a of the photosensitive resin remaining on the surface of the metal layer 11 as an etching resist, the metal layer 11 is etched.

As an etching agent used for etching the metal layer 11, an etching agent that is used in usual etching by a person skilled in the art is employable though it varies depending upon the metal of the metal layer 11. Especially when an etching solution containing an inhibitor for inhibiting side etching and a sulfuric acid-based or hydrochloric acid-based mixed liquid containing a metal salt and an oxidizing agent is used as an etching agent for copper, copper alloy, nickel or nickel alloy, the metal layer can be efficiently etched in a short period of time, and side etching hardly occurs during the etching step. Therefore, this etching solution is particularly preferable as an etching solution used for producing the wiring board-forming mold of the present invention.

In FIG. 2(c), the metal layer 11 that has been half-etched using, as an etching resist 13a, the cured body of the photosensitive resin formed as above is shown.

Through the half etching, the metal layer 11 that is not protected by the etching resist 13a is etched, while the metal layer that is protected by the etching resist 13a is not etched and remains, whereby the metal pattern 14a, such as a metal pole, having almost the same upper surface shape as that of the etching resist 13a is provided in the form of a trapezoid at about right angles to the remaining metal layer 11.

After etching of the first time is carried out as above, the etching resist 13a made of the photosensitive resin cured body and used as an etching resist in the etching of the first time is preferably removed by, for example, alkali cleaning, if necessary. By removing the etching resist, a mold can be highly precisely produced. The alkali cleaning solution used herein is, for example, a 0.5 to 1% NaOH aqueous solution.

After the etching of the first time is carried out as above, etching is carried out again while the residual metal layer 11, the mold pattern formed in the above step and the surface of the portion to be provided with a new mold pattern are protected by a pattern (etching resist) 13b of a photosensitive resin cured body formed in the same manner as above, whereby a new mold pattern is formed on the surface of the metal layer 11 where the aforesaid mold pattern is not provided.

That is to say, the top of the mold pattern 14a formed in the first etching step and the surface of the metal layer 11 where the mold pattern 14a is not provided are coated with a photosensitive resin to newly form a photosensitive resin layer 13, as shown in FIG. 2(d). On the surface of the photosensitive resin layer 13 newly formed, a mask 16 of a desired pattern is placed, and the photosensitive resin layer 13 is exposed to light and developed to form a pattern made of a cured body of the photosensitive resin, as shown in FIGS. 2(d) and 2(e). Using this pattern as an etching resist 13b, the metal layer 11 is etched, and as a result, a mold pattern 14b that is lower than the mold pattern 14a can be formed in addition to the mold pattern 14a formed in the previous step, as shown in FIG. 2(f). The etching resist 13b used herein is preferably removed by alkali cleaning or the like for the aforesaid reason.

If half etching is carried out in the etching step of the second time, the metal layer 11 can be allowed to remain, as shown in FIG. 2(f). Thereafter, on the surface of the thus remaining metal layer 11, a photosensitive resin layer 13 is formed, then the photosensitive resin layer 13 is exposed to light and developed using a mask 16 to form a pattern (etching resist) 13c of the photosensitive resin cured body, and etching is carried out in the same manner as above, whereby a mold pattern 14c can be formed, as shown in FIG. 2(g).

In the embodiment shown in FIG. 2r three-stage etching is carried out to form mold patterns 14a, 14b and 14c of different heights, as shown in FIG. 2(i). The portion of the metal layer 11 where the mold patterns 14a, 14b and 14c are not formed is removed by etching, and the support base 12 is exposed at the portion where the mold patterns 14a, 14b and 14c are not formed.

When the mold patterns 14a, 14b and 14c formed on the surface of the support base 12 are observed in the same section, the width of each of the tops 14a-t, 14b-t and 14c-t is narrower than the width of each of the bottoms 14a-b, 14b-b and 14c-b on the side of the support base 12. That is to say, regarding a single mold pattern, the contact time of the top 14a-t, 14b-t or 14c-t of the mold pattern with the etching solution is longer than the contact time of the bottom 14a-b, 14b-b or 14c-b on the side of the support base 12 with the etching solution. Therefore, the mold pattern 14 is formed in such a manner that the pattern width is gradually narrowed from the bottom 14a-b, 14b-b or 14c-b on the side of the support base 12 toward the tip, and the top 14a-t, 14b-t or 14c-t of the mold pattern 14 has the narrowest sectional width. Accordingly, the section of the mold pattern 14 has an almost trapezoid shape.

If such a tapering mold pattern 14 is formed in the wiring board-forming mold 10 of the present invention as above, the following advantages are obtained. In the case where the mold patterns 14a and 14b are allowed to penetrate into an uncured resin 34, then the resin is cured and the wiring board-forming mold 10 is removed (demolding), the mold pattern 14 can be easily released from the resin cured body. In particular, adhesion of the resin cured body to the slope face of the mold pattern 14 does not take place in the demolding, and mold pressing can be carried out without frequently cleaning the wiring board-forming mold 10 of the present invention.

In the above embodiment, half etching is carried out in the first etching step so that the metal layer 11 should remain. Therefore, the metal layer 11 needs to be further etched, but the metal layer 11 can be removed by one etching step. The wiring board-forming mold of the present invention obtained by carrying out the etching step once can be used as a mold for forming a via hole that passes through insulating film or an insulating substrate from the front surface to the back surface.

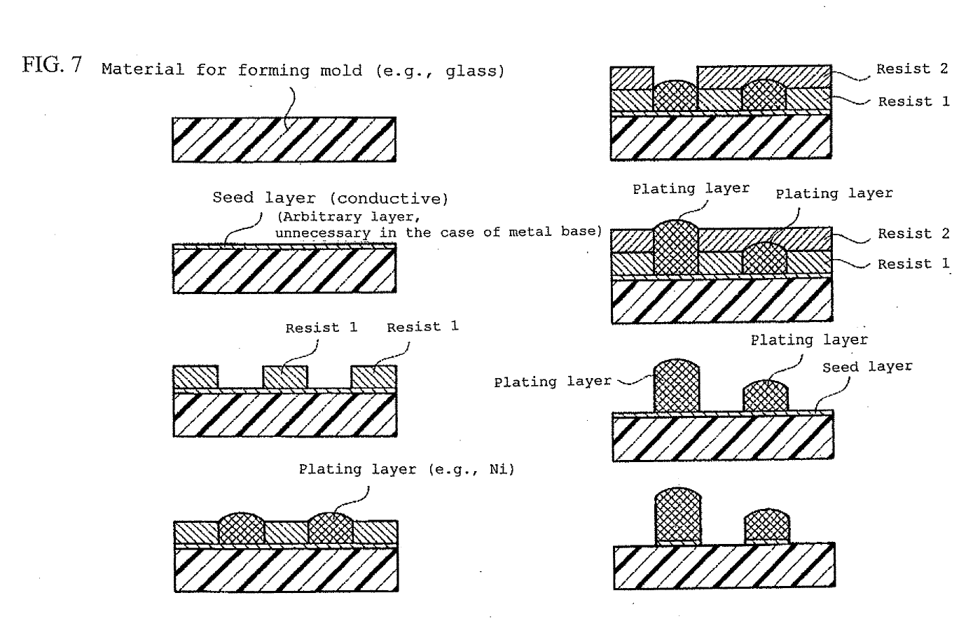

The wiring board-forming mold of the present invention can be produced also by a method other than the above etching method, such as a selective plating method, as shown in FIG. 7. That is to say, in the case where the support base is the aforesaid glass plate, on the glass is formed a metal seed layer having high bond strength to the glass, and then the glass seed layer is coated with a resist except the portion where a mold pattern is to be formed. At the portion coated with no resist, the seed surface of the support base is exposed, and the support base having this exposed seed surface where a mold pattern is to be formed is subjected to plating treatment of the first time, whereby a plating layer is formed on the exposed surface of the support base. By forming plural exposed portions on the support base and then subjecting the portions to plating treatment, plural plating layers having the same height (plating layer thickness) can be formed. The plural plating layers thus formed become mold patterns of the wiring board-forming mold of the present invention. In the case where mold patterns of different heights are formed in such a wiring board-forming mold, the first plating is carried out in the above manner to form mold patterns. Of the mold patterns, a mold pattern, whose height is intended to be increased, is left as it is, and a mold pattern, whose height is intended to be maintained as it is, is coated with a resist, followed by plating. Because the surface of the mold pattern, whose height is intended to be kept as it is, is coated with a resist, a plating layer is not laminated in this plating treatment, but on the mold pattern having no resist thereon, a new plating layer is laminated, and by virtue of lamination of the plating layer, the height of the mold pattern from the surface of the support base can be increased. By repeating such operations of coating with a resist and plating, plural mold patterns different in height from the support base can be formed. The plating layer to constitute the mold pattern is preferably made of a hard metal, and for example, a Ni plating layer can be formed. In the mold pattern formed as above, the width of the bottom portion on the support base side is larger than the width of the tip portion because the contact time of the bottom portion with the plating solution is longer. Consequently, the resulting mold pattern has a sectional shape of a trapezoid, similarly to the aforesaid mold pattern obtained by etching.

After the mold pattern is formed by plating treatment as above, the resist layer is removed by the use of, for example, an alkali cleaning solution or an organic solvent.

The wiring board-forming mold of the present invention can be produced also by laser processing. That is to say, a base material capable of becoming a mold, such as glass, is subjected to laser etching with stepless-changing laser intensity, whereby the same mold pattern as above can be formed on the support base.

Next, the process for producing a wiring board using the wiring board-forming mold obtained as above is described.

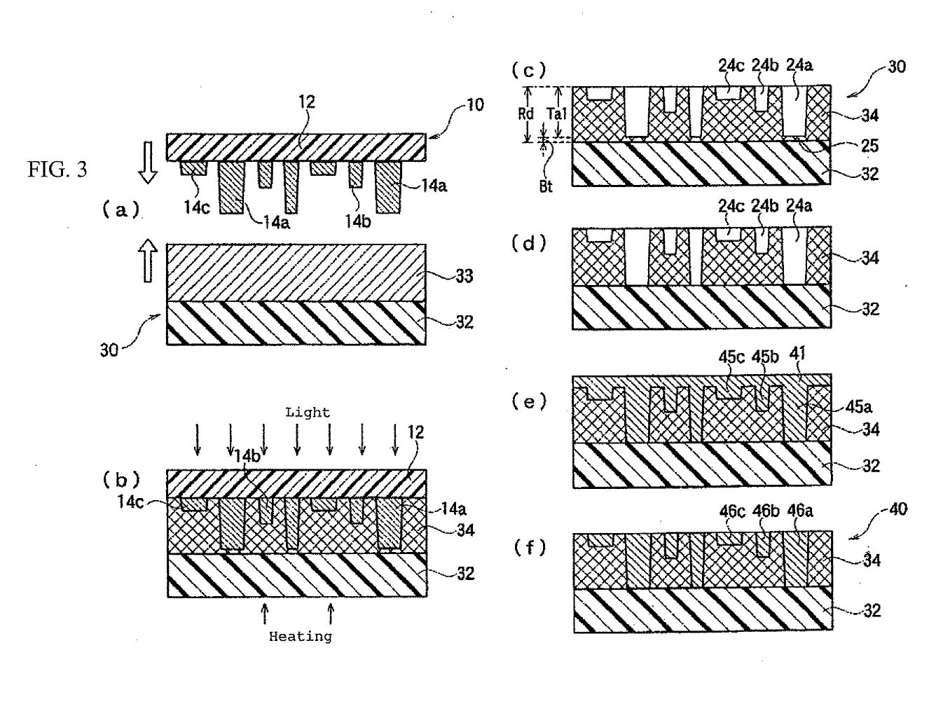

FIGS. 3(a) to 3(f) are each a sectional view in an embodiment of the process for producing a wiring board of the present invention using the wiring board-forming mold of the present invention.

Referring to FIG. 3(a), numeral 10 designates a wiring board-forming mold of the present invention produced in FIG. 2. In this figure, contrary to the mold shown in FIG. 2, a support base 12 is positioned on the upper side, and from the lower surface of the support base 12, a mold pattern is hung downward. In FIG. 3(a), numeral 30 designates a laminate in which an uncured or semi-cured curing resin layer 33 is arranged on a surface of a support 32. The uncured curing resin layer 33 is cured to form an insulating layer, and therefore, the curing resin used herein is cured to form an insulating layer.

The curing resin is, for example, a precursor or a semi-cured resin (resin in B-stage) of a thermosetting or photo-curing polyimide, a thermosetting or photo-curing epoxy resin or a thermosetting or photo-curing urethane resin. The wiring board produced by the present invention is preferably excellent in properties, such as heat resistance, water resistance, alkali resistance, acid resistance and dimensional stability (e.g., heat shrinkage/thermal expansion resistance) because heating, cooling, water-contact, drying, etc. are repeatedly carried out in various steps, such as heating step, etching step, water rinsing step, metal diffusion step, plating step and bonding step, in the production of the wiring pattern. Of the above-mentioned resins, a thermosetting and/or photo-curing polyimide or a thermosetting and/or photo-curing epoxy resin is preferably employed.

The uncured or semi-cured curing resin is preferably a resin which is cured in a short period of time upon application of heat and/or irradiation with light and which has shape holding property of such a degree that the shape formed in the wiring board-forming mold can be held even after the mold is removed.

Although the support 32 to constitute the laminate 30 has only to be one having at least self-shape holding property to hold the uncured curing resin layer 33, the support 32 is preferably formed from a conductive metal so that a protruded wiring pattern can be formed on the back surface of the cured resin layer (insulating layer) 34 after curing of the uncured photosensitive layer as described later. When a conductive metal is used for the support 32, copper, copper alloy, aluminum, aluminum alloy, silver, silver alloy or the like is employable as the conductive metal. When such a conductive metal is used, the thickness of the support 32 is in the range of usually 1 to 40 μm, preferably 2 to 20 μm.

In the case where copper is used for the support 32, any of an electrodeposited copper foil or a rolled copper foil is employable.

For producing a wiring board using the wiring board-forming mold 10 in the present invention, the mold pattern 14 of the wiring board-forming mold 10 of the present invention is allowed to penetrate into the uncured or semi-cured curing resin layer 33 formed on the surface of the support 32 of the laminate 30, as shown in FIG. 3(a). FIG. 3(b) shows the mold pattern 14 that is allowed to penetrate into the photosensitive resin layer 33, and in the stage of penetration of the wiring board-forming mold 10, the curing resin layer 33 is not cured, and by pressing down the mold pattern 14 together with the support base 12, the mold pattern 14 pushes the uncured curing resin aside and comes into the curing resin layer.

After the mold pattern is allowed to penetrate into the curing resin layer 33 as above, the curing resin 33 is heated and/or irradiated with light to be cured.

In the case where the photosensitive resin layer is photo-cured in the present invention, light irradiation to cure the photosensitive resin layer 33 is carried out from the side of the light-transmitting base 12 formed in the wiring board-forming mold 10 of the present invention. That is to say, any metal is not present on the surface of the support base (light-transmitting base) 12 where the mold pattern 14 of the wiring board-forming mold 10 has not been formed, and therefore, this portion transmits light to cure the photosensitive resin 33 of the laminate 30. On the other hand, the mold pattern 14 is formed from a metal and this portion does not transmit light. For this reason, it is probably considered that the curing resin in this portion is not cured. However, at least a part of the photosensitive resin that is not directly irradiated with light because of the mold pattern 14 undergoes photo-curing reaction attributable to light diffraction, light reflection or the like. In this case, the ratio between the area of the light-transmitting portion of the mold and the area of the pattern is preferably in the range of 80:20 to 20:80. The energy of light irradiation to cure the photosensitive resin is in the range of usually 50 to 2000 mJ/cm², preferably 100 to 1000 mJ/m². When ultraviolet light having a wavelength of 350 to 450 nm is used, the irradiation time is in the range of 5 to 120 seconds, preferably 15 to 50 seconds.

By irradiating the photosensitive resin with light through the light-transmitting base 12 of the wiring board-forming mold 10 as above, at least a part of the photosensitive resin is cured, and therefore the shape transferred to this photosensitive resin layer 33 is not broken even if the wiring board-forming mold is removed.

In the case where the curing resin layer 33 is formed from a thermosetting resin, a heating means is set on a press, and after the mold pattern 14 is allowed to penetrate, the thermosetting resin is heated to be cured. The temperature in this case varies depending upon the thermosetting resin used. However, if a thermosetting epoxy resin precursor or a semi-cured epoxy resin is used, the resin is heated at a temperature of usually 100 to 200° C., preferably 130 to 200° C., for 15 to 180 minutes, preferably 30 to 90 minutes, whereby a cured body of the curing resin can be formed.

The curing resin is cured by light or heat, and in order to perform curing reaction more efficiently, both light irradiation and heating may be carried out. When heat and light are used in combination for the curing reaction, heating is carried out for the above heating time under such temperature conditions that the curing reaction rapidly proceeds, and then light irradiation is carried out for a short period of time, whereby the curing reaction can be efficiently completed.

In the present invention, after the cured body 34 of the curing resin layer 33 in the laminate 30 is formed by light irradiation or heating as above, the wiring boards forming mold 10 is removed as shown in FIG. 3(c), and as a result, gaps 24a, 24b and 24c corresponding to the mold patterns 14a, 14b and 14c are formed in the cured body 34 of the curing resin layer 33. The curing resin layer cured body formed by curing the curing resin layer 33 becomes an insulating layer 34 in the wiring board.

As previously described, the thickness Rd of the curing resin layer 33 is slightly larger than the height Ta1 of the highest mold pattern 14a among the mold patterns 14 formed in the wiring board-forming mold, and a residual layer 25 of the curing resin layer, which has a thickness Bt (thickness difference) that is a difference between the thickness Rd of the photosensitive resin layer 33 and the height Ta1 of the highest mold pattern 14, remains on the surface of the support 32. On the inside wall surfaces of the gaps 24a, 24b and 24c formed by removing the wiring board-forming mold 10, resin residues sometimes remain.

In the present invention, a treatment to remove the residual layer 25 present at the bottom of the deepest gap 24a formed in the insulating layer 34 (cured body of curing resin layer) so that the bottom of the deepest gap 24 should be joined to the support 32 and further to remove residues remaining in the gaps 24a, 24b and 24c is desirably carried out.

The residual layer 25 present at the bottom of the gap 24a can be removed by desmearing treatment. By carrying out desmearing treatment, the residual layer 25 present at the bottom of the deepest gap 24a can be removed, and the upper surface of the support 32 is exposed at the bottom of the deepest gap 24a. Further, smears (residues) sometimes remaining inside the gaps 24a, 24b and 24c can be removed.

In FIG. 3(d), a section of a substrate having been subjected to desmearing treatment as above is shown. As shown in FIG. 3(d), the upper surface of the support 32 laminated onto the insulating layer 34 is exposed at the bottom of the deepest gap 24a.

In the present invention, a conductive metal is then deposited on the surface of the insulating layer 34 having the thus formed gaps. Deposition of the conductive metal is carried out not only on the surface of the insulating layer 34 but also inside the gaps 24a, 24b and 24c, so that the inside of the gaps 24a, 24b and 24c are filled with the deposited metal. The deposited metal layer 41 is formed so as to cover the whole surface of the insulating layer 34.

The deposited metal layer 41 forms a via hole conductor that electrically connects depressed wiring patterns or wiring patterns in the thickness direction and is formed from a conductive metal. Examples of the conductive metals include copper, copper alloy, tin, tin alloy, silver, silver alloy, gold, gold alloy, nickel, nickel alloy, and alloys containing these conductive metals. In the present invention, copper or copper alloy is preferably used as the conductive metal to be deposited.

Although such a metal can be deposited by any of a dry process and a wet process, it is preferably deposited by electroless plating and/or electroplating in the present invention. As an electroless plating solution or an electroplating solution, a plating solution hitherto used and suitable for hole filling is employed. Through the plating, a conductive metal is deposited and filled in the gaps 24a, 24b and 24c, and besides, the metal is deposited also on the surface of the insulating layer 34 to form a conductive layer 41 of usually 0.01 to 15 μm, preferably 0.5 to 3 μm. The tip of the conductive metal layer 45a filled in the deepest gap 24a formed in the insulating layer 34 reaches the support 32 and is in contact with the support 32, while the other end thereof is present on the opposite side surface to the support 32 side surface of the insulating layer 34, so that the conductive layer 45a filled in the deepest gap 24a becomes an electrical connection portion for electrically connecting the front and the back surfaces of the insulating layer 34 to each other.

After the deposited metal layer 41 is formed as above, the deposited metal layer 41 on the surface of the insulating layer 34 is polished to expose the surface of the insulating layer 34, as shown in FIG. 3(f). Examples of polishing methods include chemical polishing and mechanical polishing, and in the present invention, any of these methods can be adopted, or these methods can be used in combination. After the step of FIG. 3(d), a barrier layer is sometimes formed by electroless nickel plating, if necessary. Polishing of the metal layer to smooth the surface is advantageous not only in fining of a wiring circuit but also in enhancement of mounting reliability.

By polishing the insulating layer 34 to expose the surface of the insulating layer 34, the conductive metal 45a filled in the gap 24a, the conductive metal 45b filled in the gap 24b and the conductive metal 45c filled in the gap 24c are insulated from one another on the surface of the insulating layer 34, and they become independent, depressed wiring patterns 46a, 46b and 46c, respectively, which are embedded in the insulating layer 34.

The depressed wiring pattern 46b and the depressed wiring pattern 46c shown in FIG. 3(f) are the same as each other in sectional area, but the area of the depressed wiring pattern 46b occupying the surface of the insulating layer 34 is ½ of the area of the depressed wiring pattern 46c occupying the surface of the insulating layer 34. That is to say, if a depressed wiring pattern of the same sectional area is intended to be formed, the depressed wiring pattern is formed deeply in the depth direction of the insulating layer 34, as indicated by numeral 46b in FIG. 3(f), whereby a wiring board of high wiring density can be produced. Further, even in the case of a fine depressed wiring pattern, if the depressed wiring pattern is formed deeply in the thickness direction, the sectional area of the depressed wiring pattern is increased, and generation of heat from the depressed wiring pattern during the electric conduction is reduced.

The depressed wiring pattern 46a is formed so as to pass through the insulating layer 34 from the front surface to the back surface, and such a depressed wiring pattern 46a can be used as a via hole for electrically connecting the front and the back surfaces of the insulating layer 34 to each other.

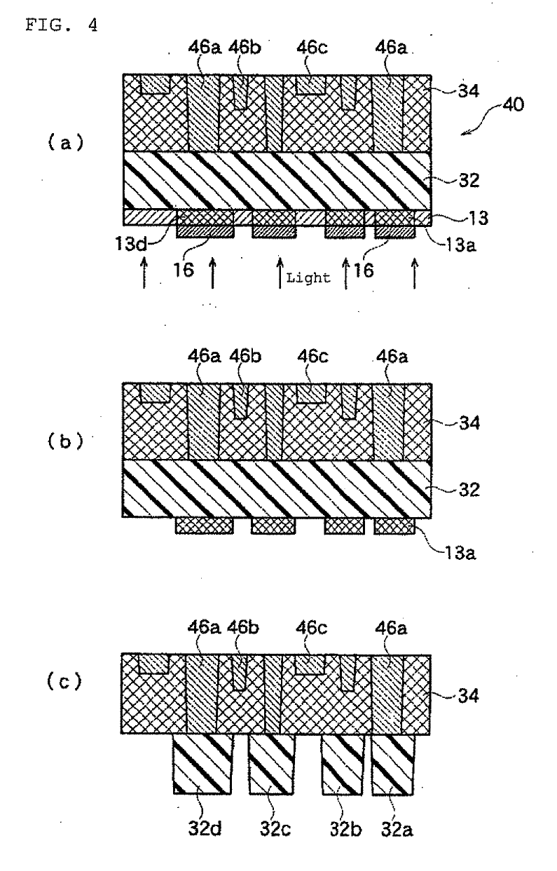

Especially when the support 32 present on the back surface side is formed from a conductive metal such as a copper foil, a double-sided wiring board in which electrical connection is made between the front and the back surfaces of the insulating layer 34 through a via hole can be produced by forming a protruded wiring pattern in a conventional manner. That is to say, after depressed wiring patterns 46a, 46b and 46c are formed in the insulating layer 34, as shown in FIG. 4(a), a photosensitive resin layer 13 is formed on the surface of the support 32 made of a conductive metal such as copper. Then, on the surface of the photosensitive resin layer 13, a mask 16 having a desired shape is placed, and the photosensitive resin layer 13 is exposed to light and developed to form a cured body layer 13a of the photosensitive resin layer 13, as shown in FIG. 4(b). Then, the support 32 is etched using the cured body layer 13a as a masking material to form protruded wiring patterns 32a, 32b, 32c and 32d, as shown in FIG. 4(c).

As shown in FIG. 4(c), the protruded wiring pattern 32a is connected, at its bottom, to the depressed wiring pattern 46a, and the protruded wiring pattern 32d is connected, at its bottom, to the depressed wiring pattern 46a. In this wiring board, on the front and the back surfaces of the insulating layer 34, independent protruded wiring patterns and independent depressed wiring patterns are formed, and besides, these wiring patterns are electrically connected to each other by means of the wiring pattern 46a (via hole) formed so as to pass through the insulating layer 34.

According to the present invention, further, a multi-layer laminated board (buildup wiring board) can be produced.

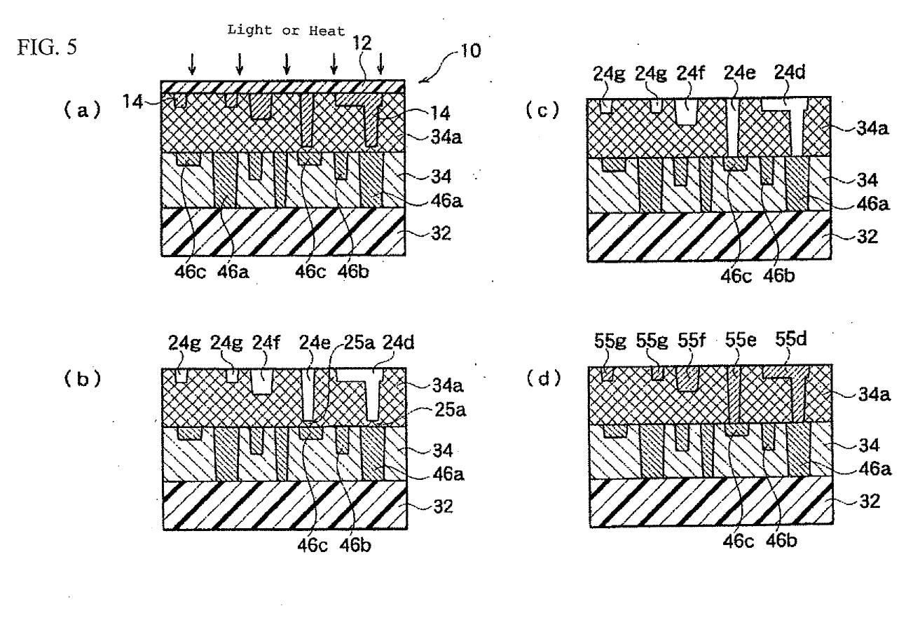

For example, a curing resin cured body (insulating layer) 34 is formed on the surface of the support 32, and depressed wiring patterns 46a, 46b and 46c are formed inside the insulating layer 34, as shown in FIG. 3. Then, an uncured or semi-cured curing resin layer is formed on the surface of the insulating layer. Thereafter, the wiring board-forming mold 10 is pressed down to allow the mold patterns 14a, 14b and 14c of the mold 10 to penetrate into the curing resin layer, as shown in FIG. 5(a). Then, the curing resin is irradiated with light from the side of the light-transmitting support base 12 of the wiring board-forming mold 10 or is heated, to cure the curing resin layer. In this curing, light irradiation may be carried out with heating the curing resin, as previously described.

After the curing resin layer is cured, the wiring board-forming mold 10 is removed to form an insulating layer 34a made of the curing resin cured body, as shown in FIG. 5(b). In the insulating layer 34a, gaps 24d, 24e, 24f and 24g having shapes corresponding to the mold patterns of the wiring board-forming mold 10 are formed. Of the gaps 24d, 24e, 24f and 24g thus formed, the gaps 24d and 24e are deepest ones, and there is a residual layer 25 between the gap 24d and the wiring pattern 46a formed under the gap 24d and between the gap 24e and the wiring pattern 46c formed under the gap 24e, so that the gap 24d and the gap 24e do not reach the wiring pattern 46a and the wiring pattern 46c present under these gaps.

Subsequently, desmearing treatment is carried out, whereby the residual layer 25 is removed to connect the gap 24d and the gap 24e to the wiring pattern 46a and the wiring pattern 46c present under these gaps, and besides, residues adhering to the inside wall surfaces of the gaps 24d, 24e, 24f and 24g are removed, as shown in FIG. 5(c).

After the desmearing treatment is carried out as above, a conductive metal is deposited inside the gaps 24d, 24e, 24f and 24g and on the surface of the insulating layer 34a, similarly to the case shown in FIG. 3(e). Then, the conductive metal deposited on the surface of the insulating layer 34a is polished so as to expose the surface of the insulating layer 34a, whereby depressed wiring patterns 55d, 55e, 55f and 55g can be made independent from one another in the width direction, as shown in FIG. 5(d). On the other hand, the depressed wiring pattern 55d is electrically connected to the depressed wiring pattern 46a of the wiring board formed under it, and the depressed wiring pattern 55e is electrically connected to the depressed wiring pattern 46c of the wiring board formed under it, and each of the depressed wiring pattern 55d and the depressed wiring pattern 55e forms a via hole that electrically connects the wiring patterns present on the front and the back surfaces of this layer to each other.

By repeating the above step, a multi-layer laminated wiring board wherein plural wiring boards are laminated can be produced.

As described above, by the use of the wiring board-forming mold of the present invention, the depressed wiring patterns 55d, 55e, 55f and 55g are formed in the insulating layer 34a, and the depressed wiring pattern formed in the insulating layer 34a and the wiring pattern formed in the insulating layer 34 present under the depressed wiring pattern can be connected to each other in the thickness direction. Moreover, the position of the via hole that connects the depressed wiring patterns in the thickness direction can be freely determined. The via hole is filled with the same conductive metal as that for forming the wiring pattern, so that the reliability about the electrical connection in the thickness direction is remarkably enhanced, and it is unnecessary to fill the via hole with a substance other than the conductive metal.

In FIG. 5, the insulating layer 34 is provided on the support 32, and this support 32 is used as it is in the lamination of a wiring board. However, if a conductive metal is used for the support 32, the support 32 can be etched to form a protruded wiring pattern, as shown in FIG. 4.

According to the present invention, the depressed wiring pattern and the via hole can be formed at the same time in the production of a multi-layer laminated wiring board, as described above. Moreover, in the via hole formed as above, any substance other than the conductive metal for forming the depressed wiring pattern is not contained, and therefore, the electrical resistivity inside the via hole does not increase.

In the above embodiment, a via hole and a depressed wiring pattern are formed at the same time. In the present invention, however, only a via hole may be formed in the insulating layer.

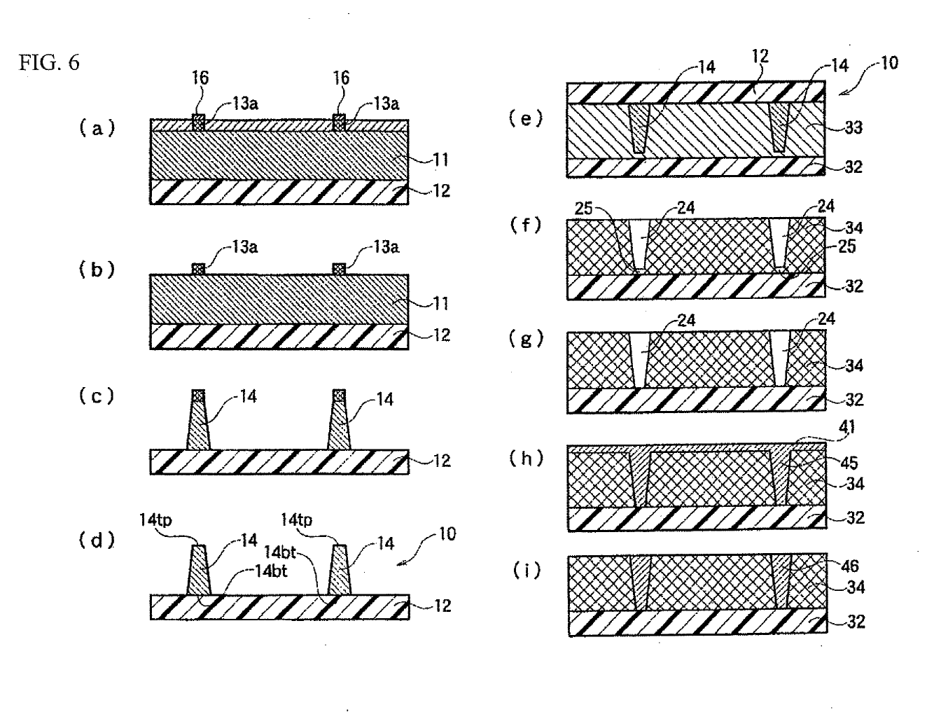

For example, a mold 10 having a mold pattern 14 for forming a via hole is formed, as shown in FIGS. 6(a) to 6(d). That is to say, a metal layer 11 is formed on a surface of a support base 12, then a photosensitive resin layer 13 is formed on the surface of the metal layer 11, and a mask 16 is placed on the surface of the photosensitive resin layer 13, as shown in FIG. 6(a). Then, the photosensitive resin layer 13 is exposed to light and developed to form a pattern 13a made of the photosensitive resin cured body (see FIG. 6(b)).

Subsequently, using the pattern 13a as a masking material, the metal layer 11 is etched to form a mold pattern 14 as shown in FIG. 6(c). The upper surface of the mold pattern formed by etching as above is protected by the pattern 13 that is a masking material, and the sectional width of the upper surface of the metal layer 11 protected by the pattern 13a is almost equal to the sectional width of the pattern 13a. However, because the metal mold pattern 14 is formed by etching the metal layer 11 using the pattern 13a as a masking material, the sectional width of the thus formed mold pattern 14 becomes gradually larger as the support base 12 is approached. In FIG. 6(d), a mold 10 obtained by removing the pattern 13a that is a masking material by means of alkali cleaning or the like is shown, and the mold pattern 14 formed in this mold 10 has a sectional shape of a trapezoid wherein the sectional width 14bt on the support base 12 side is larger than the top sectional width 14tp of the mold pattern 14.

In FIG. 6(e), the mold 10 formed as above is allowed to penetrate into an uncured or semi-cured curing resin layer 33 formed on a surface of a support 32, to transfer the shape of the mold pattern 14 of the mold 10 to the uncured or semi-cured curing resin layer 33. After the mold pattern 14 is allowed to penetrate into the curing resin 33 as above, the curing resin layer 33 is cured by heating or light irradiation to obtain a curing resin cured body 34. The curing resin cured body 34 thus obtained becomes an insulating layer 34 in the wiring board.

After the curing resin layer 34 is cured as above, the mold 10 is removed, whereby a gap 24 having a shape corresponding to the mold pattern 14 is formed in the insulating layer 34, as shown in FIG. 6(f).

In order to prevent occurrence of breakage of the tip of the metal mold pattern 14, the thickness of the curing resin layer is made a little larger than the height of the mold pattern 14, and a residual layer 25 is usually allowed to remain on the bottom of the gap 24. In order to form a via hole, therefore, this residual layer 25 needs to be removed.

To remove such a residual layer 25 and to remove residues (smears) remaining on the inside wall of the gap 24, desmearing treatment is carried out in the present invention.

By carrying out desmearing treatment as above, the gap 25 passes through the insulating layer 34 and reaches the support present under the insulating layer 34.

After the through hole is formed, a conductive metal 45 is deposited in the through hole and on the insulating layer surface, whereby the through hole is filled with the conductive metal, and also on the surface of the insulating layer 34 where no through hole is formed, a deposit layer 41 of the conductive metal 45 is formed.

Then, the thus formed deposit layer 41 of the conductive metal is polished until the insulating layer 34 is exposed, and as a result, the deposit layer 41 of the conductive metal on the surface of the insulating layer 34 can be removed to form a via hole 46.

The via hole 46 is formed by filling the gap 24 with the conductive metal, so that it exhibits remarkably high reliability as a via hole to secure electrical connection between the front and the back surfaces of the insulating layer 34.

Further, the via hole can be formed at any position in the insulating layer 34, and the area of the via hole occupying the surface of the wiring board can be decreased. According to this process, furthermore, there is no need to restrict the transverse sectional shape of the via hole to that adopted in the conventional via hole, such as circular or almost circular shape, and for example, a belt-shaped via hole can be formed.

After the via hole 46 is formed as above, a protruded wiring pattern can be formed by forming a conductive metal layer on the surface of the insulating layer 34, then further forming a photosensitive resin layer on the conductive metal layer, the exposing and developing the photosensitive resin layer and selectively carrying out etching. Further, a wiring pattern can be formed by forming a photosensitive resin layer directly on the surface of the insulating layer 34, exposing and developing the photosensitive resin layer to form a desired pattern and newly depositing a conductive metal using the thus formed pattern as a masking material. In the above description, polishing of the metal layer of FIG. 6(h) is carried out until the insulating layer 34 is exposed. Instead, it is also possible that a photosensitive resin layer is formed on the surface of the deposited conductive metal layer, then the photosensitive resin layer is exposed to light and developed to form a desired pattern made of the photosensitive resin cured body, and the deposited conductive metal layer is selectively etched using the pattern as a masking material to form a wiring pattern.

When a conductive metal is used for the support 32 present on the back surface side of the insulating layer 34, a wiring pattern can be formed also on the back surface side of the insulating layer 34 by forming a photosensitive resin layer on the surface of the support 32 made of the conductive metal, then exposing and developing the photosensitive resin layer to form a desired pattern and selectively etching the support 32 made of the conductive metal using the thus formed pattern as a masking material, similarly to the case shown in FIG. 4.

The thus obtained double-sided wiring board having wiring patterns on both surfaces can be used as a wiring board as it is. Further, this double-sided wiring board can be used as a wiring board for producing the aforesaid multi-layer laminated wiring board, and on the surfaces of the double-sided wiring board, plural wiring boards can be further laminated.

The wiring board-forming mold used in the present invention comprises a support base and a mold pattern formed by selectively etching a metal layer laminated on the surface of the support base, and because of properties of the metal etching, the sectional width of the top of the mold pattern is necessarily smaller than the sectional width of the mold pattern on the support base side. In the present invention, the wiring board-forming mold is allowed to penetrate into an uncured curing resin layer, then the curing resin is cured to convert the curing resin to an insulating layer, and thereafter, the wiring board-forming mold is removed from the insulating layer. In this case, the wiring board-forming mold having the mold pattern of the above shape can be easily removed. In particular, the mold pattern has a sectional shape of a trapezoid wherein the sectional width of the mold pattern is gradually narrowed toward the top because the mold pattern is formed by etching. Moreover, because the curing resin is slightly shrunk when it is cured, demolding becomes very easy.

By the use of the wiring board-forming mold of the present invention, formation of a depressed wiring pattern in the insulating layer and formation of a via hole that passes through the insulating layer can be simultaneously carried out. Further, because the metal to form the depressed wiring pattern and the metal to form the via hole are the same as each other, the depressed wiring pattern and the via hole do not change in electrical properties.

If the etching conditions for forming the wiring board-forming mold of the present invention are changed, the height of the mold pattern can be changed. Accordingly, the sectional area of the wiring pattern having influence on the electrical resistance of the wiring pattern can be controlled by the depth of the wiring pattern formed in the insulating layer. In a conventional wiring board obtained by selectively etching a conductive metal layer formed on an insulating film surface, it is considered as difficult to make the width of the wiring pattern narrower than 35 μm because the electrical resistance is increased. In the production of a wiring board using the wiring board-forming mold of the present invention, even if the line width is less than 35 μm, the wiring pattern can be made to have a sectional area of a certain value or more by forming the wiring pattern deeply in the depth direction of the insulating layer. Accordingly, ultrafining of a wiring pattern becomes possible.

Next, a process for producing a novel wiring board that is different from the above wiring board and a wiring board obtained by the process are described in detail.

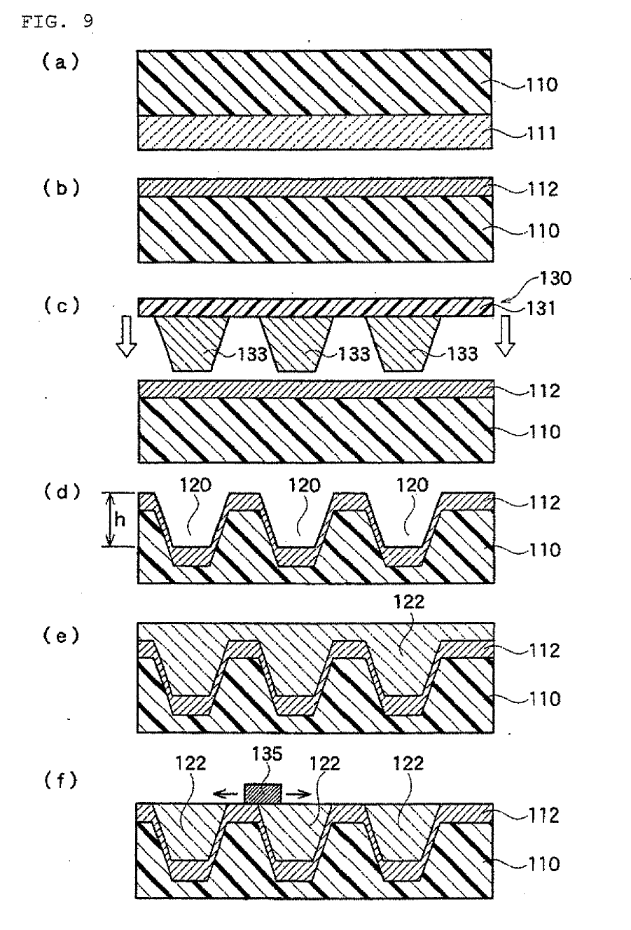

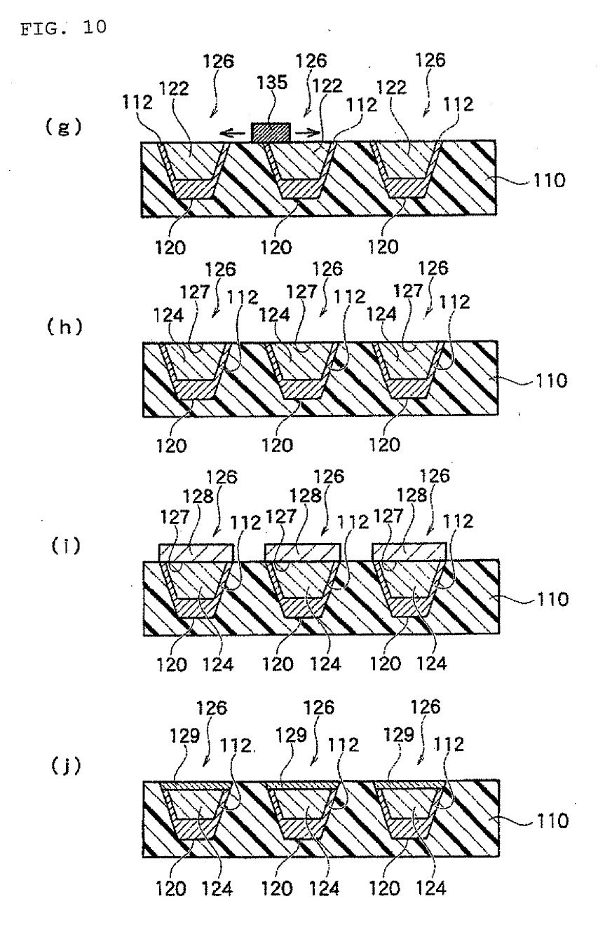

In FIG. 9 and FIG. 10, a section of a substrate in each step of the process for producing a wiring board of the present invention is schematically shown.

Referring to FIG. 9(a), an organic insulating base for use in the present invention is designated by numeral 110. The organic insulating base 110 can be formed from an organic material having electrical insulation properties. Examples of the organic insulating materials employable for the organic insulating base 110 include a liquid crystal polymer, an epoxy resin, a polyimide and a cured or uncured laminated sizing agent. The laminated sizing agent is, for example, “X paste” available from Tomoegawa Co., Ltd.

The organic insulating base 110 usually has flexibility. The epoxy resin, the polyimide resin, the cured laminated sizing agent and the like are often rigid. If such a rigid resin is adopted, a resin in a soft state, such as an epoxy resin curing precursor, a polyamic acid or an uncured laminated sizing agent, is used in the step of using a precision mold, and in the later step, the resin can be cured by heating or light irradiation. In the case where the organic insulating base 110 is used with curing the resin as above, a support for applying an uncured resin thereto is employable. In FIG. 9(a), the support is designated by numeral 111. The support 111 supports the organic insulating base 110 in the course of the formation of the organic insulating base 110 and does not necessarily have to have insulation properties. As the support 111, for example, an electrodeposited copper foil, a metal foil such as an aluminum foil, or a synthetic resin film is employable. The support 111 holds the organic insulating base 110 whose shape has not been fixed because curing is not completed. After the shape of the organic insulating base 110 is fixed, the support 111 can be removed by peeling, or the support 111 can be left to form a part of the organic insulating base 110.

Accordingly, the organic insulating base 110 for use in the present invention may have a monolayer structure or a multi-layer structure with the proviso that the layer where a depression is formed by the mold has insulation properties and flexibility as above.

The thickness of the organic insulating base 110 is such a thickness that the depression can be formed therein by a mold. The depth of the depression is in the range of usually about 5 to 30 μl, and the thickness of the portion where the depression of the organic insulating base 110 is formed is larger than the depth of the depression. When a monolayer organic insulating base 110 is used, the thickness of the organic insulating base 110 is in the range of usually about 12.5 to 75 μm, and when a multi-layer organic insulating base 110 is used, the thickness of the organic insulating base 110 is in the range of usually about 12.5 to 50 μm.

In the present inventions a metal thin film 112 is formed on one surface of the organic insulating base 110.

The metal thin film 112 is formed from a metal of excellent extensibility having a thickness of usually 0.1 to 1 μm, preferably 0.2 to 0.8 μm. By forming a metal thin film of such a thickness, the metal thin film hardly suffers defects such as cracks even when a mold is pressed. From the viewpoint of prevention of breakage caused by pressing, a metal thin film having an elongation e of not less than 0.07 is preferably adopted, and a metal thin film having an elongation e of not less than 0.2 is more preferably adopted. Although the upper limit of the elongation e is not specifically restricted, it is experimentally about 0.5. By the use of the metal thin film having such an elongation e, defects such as cracks hardly occur. The elongation e of the metal thin film is a value obtained by dividing an extended length, which is given when a metal thin film of a prescribed length is extended until the film is broken, by the original length of the metal thin film. For example, in the case where a metal thin film having a length of 10 mm is extended and is broken when the length is 13 mm, (13 mm−10 mm)/10 mm=0.3. That is to say, the elongation e of this metal thin film is 0.3 (dimensionless).

In the present invention, the metal thin film having such properties can be formed by, for example, the following methods.

The first method is a method in which electroless copper plating is carried out on the organic insulating base 110 to form a metal thin film of excellent extensibility.

In this method, electroless copper plating is preferably carried out after the organic insulating base 110 is subjected to activation treatment so that copper should be easily deposited on the surface of the organic insulating base 110. As the activation treatment, particularly preferable is a method in which a catalyst is adsorbed on the surface of the organic insulating base 110 so that copper should be easily deposited on the surface of the organic insulating base 110 by electroless copper plating. For the adsorption of a catalyst, the surface of a resin for forming the organic insulating base is swollen first, and then this surface is treated with an oxidizing agent such as potassium permanganate to remove the surface layer by oxidation. This surface is then neutralized and treated with a conditioner such as MK 140 available from Muromachi Technos Co., Ltd. Through this treatment, the surface of the organic insulating base can be imparted with activity of catalyst adsorption. After the surface of the organic insulating base is subjected to the activation treatment for catalyst adsorption, this surface is subjected to microetching using a microetching solution containing an etching agent such as potassium persulfate to remove an oxide from the surface. Then, a treatment with a sulfuric acid aqueous solution is carried out to remove potassium persulfate residues sometimes remaining on the surface of the organic insulating base.

The organic insulating base having been subjected to the surface conditioning as above is allowed to adsorb a catalyst for metal deposition, such as Pd—Sn catalyst. The adsorption of the Pd—Sn catalyst is carried out by dipping the organic insulating base in a solution containing the catalyst. Although the organic insulating base may be dipped in a Pd—Sn catalyst-containing solution directly, the organic insulating base may be temporarily dipped in a pre-dipping solution containing the Pd—Sn catalyst and then further dipped in a Pd—Sn catalyst-containing solution, whereby the Pd—Sn catalyst-containing solution hardly suffers deterioration.

By dipping the organic insulating base in the Pd—Sn catalyst-containing solution as above, the Pd—Sn catalyst is adsorbed on the surface of the organic insulating base.

The organic insulating base on which the Pd—Sn catalyst has been adsorbed is pulled up and rinsed with water, whereby most of Sn adsorbed on the organic insulating base surface is removed, and only the adsorbed Pd remains on the surface. In order to further enhance catalytic activity of the organic insulating base surface having adsorbed Pd, the surface is treated with a sulfuric acid-based agent such as KM-370 available from Muromachi Technos Co., ltd. Thereafter, a copper layer is formed by electroless copper plating.

The organic insulating base surface having adsorbed Pd exhibits a high activity for the electroless copper plating, so that copper can be efficiently deposited from the electroless copper plating solution, and the electroless copper plating layer made of the deposited copper exhibits excellent extensibility.

The second method is a method in which a copper foil having a thickness of about 5 to 10 μm is laminated on the organic insulating base 10, then the laminate is subjected to heat treatment to perform annealing, and the annealed copper foil is half-etched into a thickness of usually 0.1 to 1 μm, preferably 0.08 to 0.5 μm. By annealing such a copper foil, excellent extensibility of the copper foil is further enhanced. In this method, the copper foil is laminated on the surface of the organic insulating base 10 and then subjected to heat treatment. It is preferable to set the heat-treating temperature so that the elongation e of the copper foil should become not less than 0.35 (not less then 35%), and specifically, the temperature for the annealing is set in the range of usually 180 to 250° C.

The copper foil having been laminated and annealed is half-etched into a given thickness. As the half-etching solution used herein, a usual etching solution is employable, and by controlling the etching time, the thickness of the residual copper foil can be controlled. A rolled copper foil is superior to an electrodeposited copper foil in extensibility, and therefore, it is preferable to use a rolled copper foil.

The third method is a method in which copper is sputtered in a thickness of 0.1 to 1 μm on the organic insulating base to form a metal thin film of excellent extensibility.

That is to say, in this method, copper is sputtered on the surface of the organic insulating base using a sputtering apparatus to form a sputtering copper layer having a given thickness. The sputtering copper layer thus formed exhibits excellent extensibility.

The fourth method is a method in which a Zn plating layer is formed on the surface of the sputtering copper layer formed as above and then subjected annealing to obtain a metal thin film. By forming a zinc plating layer on the surface of the sputtering copper layer and then heating a laminate of the copper layer and the zinc plating layer to a temperature of usually 160 to 280° C., copper and zinc constituting the respective layers are diffused mutually to form an alloy layer. The thickness of the alloy layer is in the range of usually 0.1 to 1 μm, preferably 0.2 to 0.8 μm.

When this method is adopted, the thickness of the sputtering copper layer is in the range of usually 0.07 to 0.7 μm, preferably 0.14 to 0.56 μm, and the thickness of the zinc plating layer is in the range of usually 0.03 to 0.3 μm, preferably 0.06 to 0.24 μm. The ratio between the thickness of the sputtering copper layer and the thickness of the zinc plating layer (Cu:Zn) is in the range of usually 8:2 to 6:4, preferably 7.5:2.5 to 6.5:3.5. A metal thin film having a thickness ratio, i.e., a thickness ratio between copper and zinc in the alloy layer, in such a range has very excellent extensibility and hardly suffers defects such as cracks.

The fifth method is a method in which a Zn—Al superplastic alloy layer is formed on the surface of the organic insulating base. The Zn—Al superplastic alloy used herein has very excellent extensibility, and the Zn—Al superplastic alloy layer can be formed by means of, for example, a usual sputtering apparatus. The thickness of the Zn—Al superplastic alloy layer is in the range of usually 0.1 to 1 μm, preferably 0.2 to 0.8 μm, as previously described.

Also by the use of a superplastic alloy other than the Zn—Al superplastic alloy, such as a Fe—Cr—Ni alloy, a Ti—Al—V alloy or an Al—Mg alloy, a superplastic alloy layer is formed in the same manner as in the case of the Zn—Al superplastic alloy, and thereby, a metal thin film having excellent extensibility equal to that of the superplastic alloy layer formed from the Zn—Al superplastic alloy can be obtained.

As a matter of course, other methods capable of forming a metal thin film having properties equivalent to those of the metal thin film of excellent extensibility formed by the above methods are adoptable in the present invention. For example, when a polyimide is used for the organic insulating base, a direct metallizing method is applicable.

In FIG. 9(b), a section of a substrate in which a metal thin film 112 with excellent extensibility is formed as above on the surface of the organic insulating base 110 is shown. The support 111 shown in FIG. 9(a) is omitted in FIG. 9(b). The support 111 is an arbitrary layer, and even when the support 111 is disposed, it can be peeled and removed at any time after the organic insulating base 111 exhibits self-shape holding property. Therefore, the support 111 is omitted in the following figures similarly to FIG. 9(b).

In the process for producing a wiring board of the present invention, a precision mold 130 is brought into contact with the metal thin film 112 with excellent extensibility formed on the surface of the organic insulating base 110 as above and pressed onto it to form a depression in the extensible metal thin film 112, as shown in FIG. 9(c).

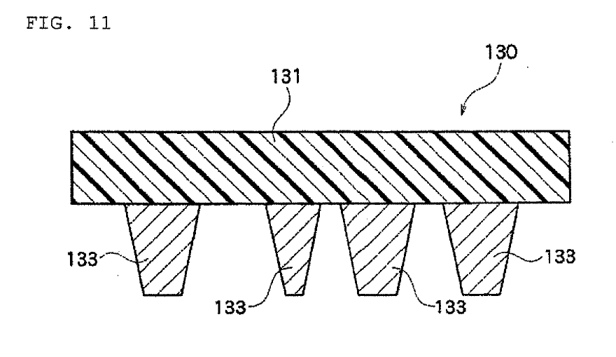

The precision mold 130 for use in the present invention generally comprises a mold base 131 to constitute this precision mold and a mold pattern 133 formed on the surface of the mold base 131, as shown in FIG. 11. The precision mold 130 may have a heating means (not shown).

The mold base 131 holds the mold pattern 133 formed in the precision mold 130 and is usually formed from a hard member, such as a metal or a resin plate, or a soft member having flexibility, such as a resin film or a resin sheet.

In the precision mold 130 for use in the present invention, a mold pattern is formed on a surface of such a mold base 131.

The mold pattern can be formed by a method comprising selectively depositing a metal on the surface of the mold base 131 or a method comprising forming a pattern on the surface of the mold base 131 and selectively etching the mold base 131 using the pattern as a masking material.

For example, a photosensitive resin layer is formed on the surface of the mold base 131, then the photosensitive resin layer is exposed to light and developed to form a desired pattern, and using the pattern as a masking material, plating treatment is carried out to deposit a metal, whereby the mold pattern can be formed. In this method, the photosensitive resin layer is exposed to light and developed so that the portion corresponding to a wiring pattern to be formed is open. Subsequently, using the thus formed pattern made of the photosensitive resin cured body as a masking material, plating treatment is carried out to form a mold pattern of a deposited metal, and then the masking material made of the photosensitive resin cured body is removed. Thus, the mold pattern is formed. Examples of the metals to constitute the mold pattern 133 include metals capable of being deposited by plating, such as nickel, copper, chromium, tin, zinc, silver and gold. By carrying out such a selective plating step at least once, the mold pattern 133 can be formed. In the case where mold patterns of different heights are formed, the above selective plating step is carried out twice or more, and mold patterns of different heights can be formed according to the number of plating treatments.

In the case where a mold pattern is formed by the use of an etchable metal, a photosensitive resin layer is formed on a surface of the metal, such as copper, iron or nickel, then the photosensitive resin layer is exposed to light and developed to form a masking material made of the photosensitive resin, and using the masking material, the metal is etched to form a mold pattern. In this method, the mold pattern is formed by etching the metal. Therefore, the shape of the masking material made of the photosensitive resin cured body is almost the same as that of the mold pattern to be formed. The etching agent for use in this method can be properly selected according to the type of the metal to be etched.

By carrying out the above etching treatment at least once, a metal mold pattern can be formed. When mold patterns of different heights are formed, the above etching treatment is carried out twice or more.

In the present invention, the mold pattern can be produced also by etching the metal by the above method to form a given pattern and then forming a plating layer on the surface of the pattern.

The mold pattern 133 formed as above can be made to have such a height that any crack in the metal thin film with excellent extensibility is not brought about by the mold. The height of the mold pattern 133 is in the range of usually 1 to 40 μm, preferably 5 to 30 μm. When a mold having a pattern of such a height is produced, defects such as cracks hardly occur in the metal thin film with excellent extensibility, and further, disconnection of the resulting wiring pattern hardly takes place in the later polishing step.

The section of the mold pattern formed as above can take any of various shapes, such as rectangle, trapezoid and triangle.

In the present invention, the precision mold 130 is brought into contact with the metal thin film 112 and pressed onto it to form a depression 120 in the metal thin film 112 having excellent extensibility, as shown in FIG. 9(d). The depression 120 has a shape corresponding to the mold pattern 133 and is directed to the deep portion of the organic insulating base 110 from the side of the metal thin film 112 with excellent extensibility.

That is to say, as shown in FIG. 9(d), on the metal thin film 112 with excellent extensibility, the precision mold 130 is disposed, and the mold pattern 133 is pushed into the organic insulating base 110 present under the metal thin film 112 with extending the extensible metal thin film 112, to form the depression 120 corresponding to the shape of the mold pattern 133. By pushing the mold pattern 133, the metal thin film 112 penetrates into the organic insulating base 110 while it is being extended. Since this metal thin film 112 has excellent extensibility as described above, defects such as cracks hardly occur, and the inside wall surface of the depression 120 formed is covered with the extended metal thin film.

In the case where a line width of a circuit surface is indicated by d, a depth thereof is indicated by h and an elongation of the metal thin film at break is indicated by e in the formation of a circuit by forming the depression 120 using the precision mold 130, the metal thin film has a relationship represented by the following formula (1):

h<1/2×d×\sqrt{e×e+e} (1)

When the elongation e of the metal thin film 112 having excellent extensibility, the line width d (μm) of a surface of a circuit to be formed and the depth h (μm) thereof satisfy the relationship represented by the above formula (1), a wiring pattern can be favorably formed.

In the present invention, the pressure applied to the precision mold 130 is in the range of usually 0.1 to 20 kg/mm², preferably 0.2 to 10 kg/mm², though it depends upon the type of the organic insulating base 110. Such pressure application may be carried out with heating. In this case, the heating temperature is in the range of usually 100 to 300° C., preferably 150 to 200° C. By applying a pressure with heating as above, penetration of the mold pattern 133 formed in the precision mold 130 into the organic insulating base 110 is facilitated, and besides, curing reaction of the resin constituting the organic insulating base 110 can be rapidly promoted by heating. By applying a pressure with heating, the shape of the organic insulating base 110 is fixed.

The time for pressing the precision mold 130 under the above conditions is in the range of usually 0.2 to 60 minutes, preferably 0.3 to 30 minutes.

After the precision mold 130 is pressed as above, the precision mold 130 is pulled up and removed.

After the depression 120 is formed in the above manner, a metal plating layer 122 having a thickness larger than the depth of the depression 120 is formed on the metal thin film 112 by plating.

In the present invention, the metal plating layer 122 is preferably formed by electroplating. By virtue of presence of the metal thin film 122 on the surface of the organic insulating base 110, electroplating can be smoothly carried out in this step.

In the present invention, it is preferable to form the metal plating layer 122 having a thickness larger than the depth of the depression 120 by electroplating, as shown in FIG. 9(e). That is to say, the depth of the depression 120 formed in the above step corresponds to the height of the mold pattern 133 is usually of 1 to 40 μm, preferably of 5 to 30 μm, while the thickness of the electroplating layer is usually 101 to 200%, preferably 110 to 150%, of the depth h of the depression 120. By setting the ratio of the thickness of the electroplating layer to the depth of the depression in the above range, the depression can be completely filled up with the deposited metal.

By forming the electroplating layer having such a thickness, the depression 120 can be filled up with the deposited metal, and also the surface of the metal thin film 12 where the depression 120 is not formed is covered with the electroplating layer.

The electroplating layer 122 is preferably an electroplating copper layer. The copper concentration of the plating solution used for the electroplating is in the range of usually 5 to 30 g/liter, preferably 8 to 25 g/liter. When such a plating solution is used, the current density is in the range of usually 0.5 to 8 A/dm², preferably 1 to 6 A/dm², and the temperature of the plating solution is set at usually 19 to 28° C., preferably 21 to 26° C.

The electroplating time under such conditions is in the range of usually 1 to 10 minutes, preferably 2 to 8 minutes.

In the present invention, after the metal plating layer 122 is formed by electroplating as above, the metal plating layer 122 is polished until the organic insulating base 110 is exposed from the surface of the metal plating layer 122, to form a wiring pattern 126 wherein the depression 120 is filled with the plating metal 124, as shown in FIG. 9(f) and FIG. 10(g).

That is to say, in this polishing step, using a polishing means 135, the metal plating layer 122 is polished from its surface and removed, and further, the metal thin film 112 present on the surface of the organic insulating base 110 is also polished and removed. By polishing in this manner, the metal thin film 112 is removed from the surface of the organic insulating base 110, and the organic insulating base 110 is exposed as shown in FIG. 10(h). On the other hand, since the depression 120 is embedded in the organic insulating base 110, the plating metal 124 filled in the depression 120 and the extensible metal thin film 112 present under the plating metal 124 are not polished, whereby a wiring pattern 126 embedded in the organic insulating base 110 is obtained. In this polishing step, rough polishing is carried out first using a brush of #200 to #320 until the surface of the organic insulating base 110 is exposed, and then surface conditioning is carried out using a buff of #600 to #800.

In the final polishing step, any of chemical polishing and physical polishing is adoptable, but physical polishing is preferable because the step is simple. When the physical polishing is adopted, not only a usual polishing brush and a usual polishing buff but also an abrasive composition containing abrasive grains is employable as the polishing means. Examples of the polishing brushes and polishing buffs employable herein include polishing brushes and polishing buffs having a roughness of #1500 or more, preferably #2500 or more.

As the abrasive composition, a composition containing alumina abrasive grains having a mean grain diameter of not more than 1 μm, preferably not more than 0.3 μm, is employable. It is preferable to successively carry out polishing operations using polishing means 135 of different roughness. By the use of such polishing means 135 successively, polishing can be efficiently carried out, and excessive polishing is not made. Therefore, the resulting wiring pattern is not damaged.

As described above, the rough polishing is preferably carried out until the surface of the organic insulating base 110 is nearly exposed. After the rough polishing, buff final polishing is carried out to smooth the copper pattern surface.

Through the buff polishing, the metal plating layer 122 and the metal thin film 112 remaining on the surface of the organic insulating base 110 are removed, whereby a number of wiring patterns 126 embedded in the organic insulating base 110 can be formed. Between the thus formed wiring patterns, only the organic insulating base 110 is present, and a number of wiring patterns 126 formed are electrically independent from their neighboring wiring patterns 126.

The upper end 127 of the wiring pattern 126 formed by the above polishing becomes flush with the surface of the organic insulating base 110.

The upper end 127 of the thus formed wiring pattern 126 constituted of the plating metal and the metal thin film with excellent extensibility is flush with the surface of the organic insulating base and is exposed, while the rest of the wiring pattern is embedded inside the organic insulating base. In the use of this wiring board, the upper end 127 of the wiring pattern 126, which is flush with the surface of the organic insulating base, is used as a connecting part. In the wiring board of such a form, solder flow does not occur.

The wiring board obtained by the above polishing can be used as it is. However, the upper end 127 of the wiring pattern 126 exposed from the surface of the organic insulating base 110 is preferably subjected to plating treatment using a metal different from the metal that forms the wiring pattern 126.

As the different metal to constitute the layer formed by the plating treatment, such a metal as is improved in wettability by solder used in the later step is preferably used.

In the case where the wiring pattern 126 is produced by depositing copper through electroplating in the present invention, the upper end 127 of the wiring pattern 126 can be subjected to tin plating, gold plating, nickel plating, gold-nickel plating, solder plating, lead-free solder plating or the like. In the present invention, tin plating or gold plating is particularly preferably carried out so that solder wettability and corrosion-proofing effect may be compatible with each other.

In FIG. 10(i), the wiring board of the present invention having been subjected to the above plating is shown, and the plating layer is designated by numeral 128.

In case of, for example, tin plating, the thickness of the tin plating layer is in the range of usually 0.1 to 0.7 μm, preferably 0.2 to 0.5 μm.

Such a tin plating layer is preferably formed by electroless tin plating or tin electroplating. As the electroless tin plating solution, a usually used tin plating solution is employable, and the tin concentration of the tin plating solution is in the range of usually 15 to 35 g/liter, preferably 19 to 29 g/liter.

In the case where the metal plating layer 128 is, for example, a gold plating layer or a tin plating layer and is formed by electroplating, this plating layer protrudes from the surface of the organic insulating base 110, as shown in FIG. 10(i). In order to maintain a smooth surface, the thickness of the plating layer thus formed is preferably not more than 0.5 μm. In the case where the tin plating layer is formed by electroless plating, tin is substituted for the copper at the surface of the wiring pattern 126 during the electroless tin plating to form an electroless tin plating layer 129, and the upper surface of the electroless tin plating layer 129 is flush with the surface of the organic insulating base 110, as shown in FIG. 10(j). Thus, the metal plating layer is preferably formed by substitutional electroless plating.

In the wiring board of the present invention produced as above, the wiring pattern 126 is formed by filling the plating metal 124, through the metal thin film 112, in the depression 120 formed in the organic insulating base 110.

On the surface of the wiring pattern 126 thus formed, the metal plating layer 128 made of a metal different from the plating metal 124 filled in the depression 120 is preferably formed.

In the wiring board of the present invention, the wiring pattern 126 is embedded inside the organic insulating base 110, and therefore, even if the interval between the neighboring wiring patterns 126 is extremely narrow, short circuit does not occur between the neighboring wiring patterns 126. In the wiring board of the present invention, accordingly, the pitch width of the wiring pattern 126 can be narrowed. In the present invention, a wiring board can be produced as long as the pitch width is not less than 20 μm. The process of the present invention is particularly suitable for producing a wiring board with a wiring pattern having a pitch width of 30 to 300 μm. The width of the wiring pattern in the wiring board of the present invention is in the range of usually 5 to 150 μm, preferably 15 to 100 μm.

According to the process for producing a wiring board of the present invention, a wiring board wherein a wiring pattern is embedded in an organic insulating base can be produced. That is to say, in the depression 120 formed in the organic insulating base 110, a plating metal is filled through the metal thin film 112 having excellent extensibility, and the upper end 127 of the wiring pattern 126 is flush with the surface of the organic insulating base 110. Since the wiring pattern 126 is embedded in the organic insulating base 110 through the metal thin film 112 with excellent extensibility and penetrates into the organic insulating base 110, adhesion between the organic insulating base 110 and the wiring pattern 126 is high. The wiring pattern 126 is formed so as to be flush with the organic insulating base 110 as described above, and therefore, if the wiring patterns 126 are used as pads for solder balls, the areas of the solder ball pads become uniform, and the heights of the solder balls do not become uneven. Further, if such wiring patterns are used as pads for solder balls, there are no corner portions in the solder ball pads, so that any vacancy is not formed in the soldering process. Consequently, reliability about the electrical connection using solder balls is enhanced.

### EXAMPLES

The present invention is further described with reference to the following examples, but it should be construed that the invention is in no way limited to those examples.

### Example 1

### Preparation of Wiring Board-Forming Mold

A surface of a glass substrate (support base) having a thickness of 5 mm was subjected to zincate treatment (zinc treatment) Thereafter, a nickel layer having a thickness of 0.3 μm was formed by electroless plating, and then a copper layer having a thickness of 20 μm is further formed by electroplating. On the surface of the copper layer, a photosensitive resin layer having a dry coating thickness of 2 μm was formed. On the surface of the photosensitive resin layer, a mask of a given pattern was placed, and the photosensitive resin layer was exposed to light and developed to form an etching resist made of a cured body of the photosensitive resin having a line width of 20 μm. Then, the copper layer was etched in the thickness direction by about ½ (about 10 μm) of its thickness (first etching step).

Subsequently, the masking material (etching resist, cured body of photosensitive resin) used in the first etching step was removed by an alkali aqueous solution, and then the surface of the copper layer was coated with a photosensitive resin in such a manner that the dry coating thickness became 3 μm. On the surface of the resulting photosensitive resin layer, a mask of a given pattern was placed, and the photosensitive resin layer was exposed to light and developed to form a second etching resist made of a cured body of the photosensitive resin having a line width of 10 μm. Then, the copper layer was etched in the thickness direction by ½ (about 10 μm) of its thickness until the glass substrate was exposed (second etching step).

After the second etching step was completed, the etching resist was removed by alkali cleaning to obtain a wiring board-forming mold of the present invention.

In the wiring board-forming mold thus obtained, a mold pattern having a height of 10 μm and a mold pattern having a height of 20 μm were provided on the surface of the glass substrate that was a light-transmitting base. The sectional width of the top of each mold pattern was 5 μm, and the sectional width of each mold pattern on the glass substrate side was 8 μm, that is, the sectional shape of each mold pattern was a trapezoid having the base width of 8 μm and the top width of 5 μm.

### Preparation of Wiring Board

A surface of an electrodeposited copper foil having a thickness of 12 μm was coated with an epoxy thermosetting resin, then air dried and heated at 120° C. for 5 minutes to prepare a resin-coated copper foil having a semi-cured resin layer. The thickness of the resin layer thus formed was 20 μm.

The above resin-coated copper foil was placed in a lower holder of a press, the wiring board-forming mold was placed in an upper holder thereof, and the mold was heated to 130° C.

The upper holder and the lower holder of the press were brought into close contact with each other so that the mold patterns formed in the wiring board-forming mold should penetrate into the resin layer of the resin-coated copper foil, whereby the depressions and the protrusions of the mold patterns of the wiring board-forming mold were allowed to penetrate into the resin layer of the resin-coated copper foil. In this operation, the wiring board-forming mold was pushed down until the highest mold pattern among the mold patterns formed in the wiring board-forming mold thrust the resin of the resin-coated copper foil aside and nearly reached the upper surface of the copper foil, and in this state, the wiring board-forming mold was held at a temperature of 180° C. for 45 minutes to cure the epoxy resin of the resin-coated copper foil.

After the lapse of 45 minutes, the upper holder of the press was pulled up to perform demolding. In the demolding operation, the resin did not adhere to the wiring board-forming mold, and release of the resin-coated copper foil from the wiring board-forming mold could be easily carried out. To the resin layer of the resin-coated copper foil thus demolded, the mold patterns of the wiring board-forming mold had been transferred, and the transferred patterns suffered no defects. Further, the mold had no defects either.

The resin-coated copper foil having the transferred patterns was subjected to desmearing treatment, whereby resin residues present on the bottom of the deepest gap were removed to expose the copper foil at the bottom of the gap, and at the same time, resin-residues inside the gaps were removed.

Subsequently, copper was deposited on the resin layer surface of the resin-coated copper foil having the gaps, to fill the gaps with copper. By depositing copper in this manner, copper was deposited also on the surface of the resin layer. Therefore, the copper deposited on the surface of the resin layer was polished until the surface of the resin layer was exposed.

After the depressed wiring pattern made of copper was formed on the resin layer side of the resin-coated copper foil, a photosensitive resin was applied onto the electrodeposited copper foil side surface of the resin-coated copper foil, and the resulting photosensitive resin layer was exposed to light and developed to form a pattern made of the photosensitive resin cured body. Using the pattern as a masking material, the electrodeposited copper foil of the resin-coated copper foil was etched with an etching solution to form a protruded wiring pattern.

Through the above operations, a double-sided printed wiring board having the epoxy resin cured body as an insulating layer, a depressed wiring pattern of a line width of 10 μm, which had been formed in a concave shape in the depth direction of the insulating layer from its one surface, and a protruded wiring pattern, which had been formed in a convex shape on the other surface of the insulating layer, could be produced. The wiring patterns formed on both surfaces of the wiring board were electrically connected to each other by means of copper filled in the gap (via hole) formed by the mold pattern of 20 μm height of the wiring board-forming mold.

The electrodeposited foil of 12 μm thickness that was a support was coated with an epoxy resin (glass transition temperature Tg: 180° C.) in a thickness of 20 μm.

The resulting epoxy resin layer was swollen, oxidized by an oxidizing agent to remove the surface layer and then neutralized. Thereafter, removal of stains and activation of catalyst adsorption were carried out using a conditioner, then microetching with potassium persulfate was carried out to remove an oxide, and persulfate residues were removed by sulfuric acid. The treating time of each of these steps was several minutes.

The epoxy resin layer formed as above was subjected to pre-dipping in a Pd—Sn catalyst in order to protect a catalyst bath, and thereafter, another Pd—Sn catalyst was adsorbed on the surface of the epoxy resin. The resulting catalyst layer was rinsed with water to remove Sn, then in order to enhance catalyst activity, treatment with a sulfuric acid-based chemical was carried out, and thereafter, the catalyst-activated epoxy resin was treated with an electroless copper plating solution for 15 minutes to form a copper film having a thickness of 0.4 μm. The resulting copper film was rinsed with water to obtain a two-layer base of 35 mm×40 mm (provided with an electrodeposited copper foil support) having the electroless plating layer of 0.4 μm thickness on the surface of the epoxy resin layer. An electroless plating layer of a two-layer base separately prepared in the same manner had an elongation e of 0.1.

On the surface of the electroless plating layer of 0.4 μm thickness of the two-layer base, a gold plating precision mold of 15 mm×15 mm wherein a pattern of a trapezoid shape having a wiring height of 10 μm and a pitch of 180 μm (line width: 100 μm, interval: 80 μm) had been formed was placed, and the gold plating precision mold was pressed with heating at 160° C. for 19.8 seconds at a pressure of 200 g/mm² with a heat tool of 3 mm width using a pulse heat type thermo-compression bonding device (Nippon Avionics Co. Ltd.) to perform thermo-compression bonding, whereby a depression corresponding to the protrusion of the gold plating precision mold was formed on the surface of the electroless copper plating layer 0.4 μm in thickness of the two-layer base.

By using the gold plating precision mold as above, a concave portion (depression) corresponding to the protrusion of the gold plating precision mold was formed in the two-layer base. The depth h of the concave portion (depression) was 10 μm. Although the concave portion (depression) was formed, any crack or the like did not occur in the electroless copper plating layer. Through the above pressing with heating, the epoxy resin was cured.

Next, using a copper sulfate plating solution (copper concentration: 18 g/liter) for through hole plating, copper electroplating was carried out at a current density of 4 A/dm² for 20 minutes at room temperature with vigorous stirring. As a result, an electroplating copper layer having a thickness of 17 μm (170% of the depth of the depression) could be formed.

Subsequently, the surface of the electroplating copper layer was subjected to rough polishing using an abrasive paper of #280, then subjected to surface conditioning using an abrasive paper of #600 and further subjected to final polishing using a buff of #1500, whereby the electroplating copper layer formed on the resin base surface was removed and the electroless copper plating layer present under the electroplating copper layer was further removed to expose the epoxy resin base.

By removing the extra electroplating copper layer by polishing as above, a wiring pattern wherein a copper electroplating metal was filled in the depression that was symmetrical to the pattern formed in the gold plating precision mold used was formed. The thus formed wiring pattern had a pitch width of 180 μm.

On the wiring pattern formed as above, electroless tin plating was carried out under the conditions of 70° C.×2.5 minutes using an electroless tin plating solution (LT-34, available from Rhom & Haas Co.) to substitute an electroless tin plating layer for the copper having a mean thickness of 0.5 μm at the surface of the wiring pattern.

Of the wiring pattern formed as above, the wiring pattern made of the electrodeposited copper penetrated into the resin base, and the electroless tin plating layer formed thereon was flush with the surface of the resin base. Also on the side of the electrodeposited copper foil that was used as a support first, copper and tin were deposited by plating, so that a two-metal board wherein these metals had no electrical connection to the above wiring pattern was obtained.

### Example 2

On a tough pitch copper rolled copper foil having a thickness of 10 μl, a liquid crystal polymer (obtained by orientation of aromatic polyester resin) of 50 μm was laminated, and they were annealed at 180° C. for 1 hour to increase the elongation of the rolled copper foil to not less than 35% (not less than 0.35). The rolled copper foil layer of this two-layer laminate (35 mm×40 mm) was subjected to half etching in such a manner that the thickness of the rolled copper foil layer became 1 μm. The elongation e of the rolled copper foil used was 0.12.

Separately from the above, a silicon precision mold (15 mm×15 mm) having a thickness of 0.2 mm wherein a wiring pattern (rectangular) having a protrusion height of 5 μm and a pitch of 50 μm (line width: 30 μm, interval: 20 μm) had been formed was prepared.

The precision mold was disposed on the copper layer surface of the resin substrate with the copper layer of 1 μm prepared as above, and the precision mold was pressed with heating at 350° C. for 5 seconds at a pressure of 200 g/mm² with a heat tool of 3 mm width (manufactured by Super Imper Co.) using a pulse heat type thermo-compression bonding device (Nippon Avionics Co. Ltd.) to perform thermo-compression bonding. As a result, a wiring groove having a depth of 5 μm and a width of 30 μm could be formed in the two-layer base.

Although the depression was formed by pressing the silicon precision mold with heating as above, any crack or the like did not occur in the rolled copper foil with excellent extensibility that had been adjusted to have a thickness of 1 μm.

Then, the precision mold was removed, and using a copper sulfate plating solution (copper concentration: 18 g/liter) for through hole plating, copper electroplating was carried out at a current density of 4 A/dm² for 15 minutes at room temperature with vigorous stirring. As a result, an electroplating copper layer having a thickness of 13 μm could be formed on the whole surface.

Subsequently, the surface of the resulting electroplating copper layer was subjected to rough polishing using an abrasive paper of #280, then subjected to surface conditioning using an abrasive paper of #600 and further subjected to final polishing using a buff of #1500, whereby the electroplating copper layer formed on the resin substrate surface and the copper foil layer of 1 μm thickness were polished and removed to expose the surface of the liquid crystal polymer that was the resin substrate.

By removing the extra plating layer by polishing as above, a wiring pattern wherein a copper electroplating metal was filled in the depression that was symmetrical to the pattern formed in the silicon precision mold used was formed. The thus formed wiring pattern had a pitch width of 50 μm.

The wiring pattern formed as above was subjected to electroless tin plating under the conditions of 70° C.×2.5 minutes using an electroless tin plating solution (LT-34, available from Rhom & Haas Co.) to substitute an electroless tin plating layer for the copper having a mean thickness of 0.5 μm at the surface of the wiring pattern.

Of the wiring pattern formed as above, the wiring pattern made of the electrodeposited copper penetrated into the resin substrate, and the electroless tin plating layer formed thereon was flush with the surface of the resin substrate made from the liquid crystal polymer.

### Example 3

On silicon having a size of 15 mm×15 mm, 16 protruded patterns each having a wiring height of 5 μm, a pitch of 30 μm (line width: 18 μm, interval: 12 μm) and a length of 10 mm were formed to prepare a precision mold.

Separately from the above, on a surface of a polyimide film (available from Ube Industries, Ltd., trade name: Upirex S), a Ni—Cr alloy (Cr content: 20% by weight) was sputtered in a thickness of 250 Å, and then Cu was further sputtered in a thickness of 2000 Å, to prepare an organic insulating base with a sputtering metal layer (e: about 0.15).

The precision mold was brought into contact with the sputtering metal layer surface of the organic insulating base with a sputtering metal layer prepared as above, and the precision mold was pressed with heating at 300° C. for 19.8 seconds at a pressure of 7550 g/mm² with a heat tool of 3 mm width using a pulse heat type thermo-compression bonding device (Nippon Avionics Co. Ltd., TCW-125) to perform thermo-compression bonding.

After the temperature was lowered to room temperature, the heat tool was pulled up, and the precision mold was removed.

It was confirmed that depressed patterns each having a depth of about 5 μm were formed on the sputtering metal layer surface of the organic insulating base with a sputtering metal layer. In the sputtering metal layer, any crack or the like was not observed.

Using a copper sulfate plating solution (copper concentration: 15 g/liter) for through hole plating, the organic insulating base with a sputtering metal layer on which depressed patterns had been formed as above was subjected to copper electroplating at a current density of 3 A/dm² for 12 minutes at a liquid temperature of 22° C. with vigorous stirring. As a result, an electroplating copper layer having a thickness of 8 μm was formed on the whole surface of the organic insulating base.

Subsequently, the surface of the electroplating copper layer formed as above was subjected to rough polishing with an abrasive paper of #280 using a rotary type polishing machine. When the surface of the polyimide film that was the organic insulating base appeared, the abrasive paper was replaced with an abrasive paper of #600, and polishing was continued to perform conditioning of abrasion flaw. Then, polishing with an abrasive paper of #1500 (available from Marumoto Struers K.K.) was further carried out while dropping a polishing liquid (available from Mirror Co.) containing dispersed abrasive grains having a mean grain diameter of 1 μm, and then final polishing with an abrasive paper of #2400 (available from Marumoto Struers K.K.) was carried out while dropping a polishing liquid containing dispersed abrasive grains having a mean grain diameter of 0.3 μm.

As a result, a wiring board having copper wiring patterns and being flush with the polyimide film (organic insulating base) having smooth and glossy surfaces was obtained. The wiring patterns formed were symmetrical to the protruded patterns formed in the precision mold.

Then, the wiring board was placed in a gold plating bath (available from EEJA Ltd., Temperex #8400), and gold electroplating was carried out at a plating solution temperature of 65° C. and a current density of 0.5 A/dm² for two minutes. As a result, a wiring board having wiring patterns on each of which a gold plating layer of 0.5 μm thickness had been formed in a protruded shape from the surface of the organic insulating base, as shown in FIG. 9(i), could be obtained.

Although the gold plating layer was not flush with the organic insulating base, there is no problem in the practical use in soldering or the like.

### INDUSTRIAL APPLICABILITY

In the wiring board-forming mold of the present invention, a mold pattern having a sectional shape of a trapezoid is formed on a base surface, and by allowing this mold pattern to penetrate into an uncured or semi-cured curing resin, a gap reverse to the mold pattern can be formed. Further, because the sectional shape of the mold pattern is a trapezoid, demolding can be easily made.

By depositing a conductive metal in the gap formed by the wiring board-forming mold as above, a depressed wiring pattern can be formed. If the depressed wiring pattern is formed deeply in the insulating layer, the depressed wiring pattern can be ensured to have a sectional area of a certain value or more, and consequently, even if the depressed wiring pattern is fined, increase of a resistance value of the depressed wiring pattern can be inhibited.

By providing a mold pattern capable of passing through the insulating layer in the wiring board-forming mold of the present invention, a via hole that passes through the insulating layer from the front surface to the back surface and a wiring pattern can be formed at the same time.

According to the process for preparing a wiring board of the present invention, depressed wiring patterns having different line widths and different line depths can be formed at the same time. Further, because the mold pattern of the mold used for producing the wiring board of the present invention has a sectional shape of a tapering trapezoid, demolding can be easily made after the mold pattern is transferred, and besides, the transferred pattern hardly suffers defects.

According to the process for preparing a wiring board of the present invention, a fine depressed wiring pattern having extremely small line width can be formed in the wiring board as described above, and in spite of such a fine wiring pattern, this wiring pattern can be provided deeply in the insulating layer. By forming the wiring pattern deeply in the depth direction, increase of an electrical resistivity of the wiring pattern can be inhibited.

Because the electrical resistivity of the depressed wiring pattern is not increased as above, generation of heat from the wiring board hardly occurs even when an electric current flows.

By using the mold in the above manner, a multi-layer laminated wiring board wherein plural wiring boards are laminated can be produced, and the thus produced multi-layer laminated wiring board has excellent reliability about the electrical connection between the laminated wiring boards. Further, a via hole to secure electrical connection in the depth direction in such a multi-layer laminated wiring board can be produced simultaneously with formation of the depressed wiring pattern. Furthermore, the area occupied to form the via hole is nearly equal to the surface area of the via hole, and an extra area such as a land is unnecessary. In such a multi-layer laminated wiring board, the via hole can be formed at any position, and therefore, the degree of freedom in designing of the wiring board becomes extremely high. Especially when via holes are formed by the process of the present invention, the via holes can be laid one upon another.

In the wiring board produced by the process of the present invention, a conductor is embedded in the organic insulating base, and therefore, even if a resin having low bond strength to a copper plating layer is used as a base, high bond strength develops between the resin base and the conductor. On this account, the range of choice of the resin employable as the base to produce the wiring board is widened. Consequently, a novel wiring board can be produced using a resin that has been considered to be difficult to use as a base because it has low bond strength to the wiring pattern though it is excellent in insulation properties, chemical resistance, heat resistance and electrical properties, and the wiring board obtained by selecting a resin base can be readily imparted with desired properties.

Moreover, the wiring board of the present invention has a structure wherein the wiring pattern is embedded in the resin, and therefore, even if the wiring pattern has a fine pitch, a solder bridge between bottoms does not occur.

Particularly in the wiring board of the present invention, the reliability about resistance to fatigue at a solder connecting portion is high, and highly reliable electrical connection can be established even if mounting is carried out using a solder ball as an external terminal.

1. A wiring board-forming mold comprising a support base and a mold pattern that is formed in a protruded shape on one surface of the support base, wherein a sectional width of the mold pattern on the support base side is larger than a sectional width thereof on a tip side in the same section of the mold pattern.

2. The wiring board-forming mold as claimed in claim 1, wherein the mold pattern is formed in the wiring board-forming mold so that by pressing the mold pattern onto an uncured or semi-cured curing resin and curing the curing resin in this state, a shape corresponding to the mold pattern can be transferred to the curing resin.

3. The wiring board-forming mold as claimed in claim 1, wherein the support base is a light-transmitting base, and the mold pattern is formed in the wiring board-forming mold so that by pressing the mold pattern onto an uncured or semi-cured photo-curing resin and exposing the photo-curing resin to light through the light-transmitting base, at least a part of the photo-curing resin may be cured to enable transfer of a given pattern corresponding to the mold pattern.

4. The wiring board-forming mold as claimed in claim 1, wherein at the portion of the wiring board-forming mold where the mold pattern is not formed, the surface of the support base is exposed.

5. The wiring board-forming mold as claimed in claim 1, wherein the support base is a light-transmitting base, and the light-transmitting base comprises quartz, a glass plate or a light-transmitting synthetic resin plate.

6. The wiring board-forming mold as claimed in claim 1, wherein the ratio (W1/W2) of the sectional width W1 of the support base side bottom of the mold pattern to the sectional width W2 of the top of the mold pattern in the same section of the mold pattern formed in the wiring board-forming mold is in the range of 1.01 to 2.0.

7. The wiring board-forming mold as claimed in claim 1, wherein on the support base surface, mold patterns of at least two heights, which differ in height from the support base surface to the top, are formed.

8. The wiring board-forming mold as claimed in claim 1, wherein the mold pattern is made of metal.

9. The wiring board-forming mold as claimed in claim 1, wherein the mold pattern is formed by etching a metal layer formed on the surface of the support base.

10. A process for producing a wiring board-forming mold, comprising carrying out, at least once, a selective etching step which comprises forming a photosensitive resin layer on a surface of a metal layer formed on one surface of a support base, exposing and developing the photosensitive resin layer to form a pattern made of photosensitive resin cured body and selectively etching the metal layer using the pattern as a masking material, to form a pattern made of metal on the surface of the support base.

11. The process for producing a wiring board-forming mold as claimed in claim 10, wherein in the selective etching step for selectively etching the metal layer using the pattern made of the photosensitive resin cured body as a masking pattern, the metal layer is half-etched and the masking material is removed, and thereafter, a re-etching step, comprising forming a photosensitive resin layer again, exposing and developing the photosensitive resin layer to form a new pattern made of the photosensitive resin cured body and selectively etching the metal layer using the thus formed new pattern as a masking pattern, is carried out at least once to form patterns of different heights made of the metal on the surface of the support base.

12. The process for producing a wiring board-forming mold as claimed in claim 11, wherein the final etching step is carried out so as to expose the surface of the support base at the portion where the patterns are not formed.

13. The process for producing a wiring board-forming mold as claimed in claim 10, wherein the support base is a light-transmitting base, and the light-transmitting base comprises a glass plate or a transparent synthetic resin plate.

14. A wiring board-forming mold for forming a pattern in a photo-curing or thermosetting resin layer, which comprises a support base and a mold pattern, wherein at least two mold patterns having different heights are formed, and among the mold patterns, the highest metal mold pattern is formed so as to be lower by 0.1 to 3 μm than the thickness of the resin layer into which said highest mold pattern is allowed to penetrate.

15. The wiring board-forming mold as claimed in claim 14, wherein a difference between the height of the highest metal pattern among the mold patterns and the thickness of the resin layer into which said highest mold pattern is allowed to penetrate is in the range of 0.1 to 3 μm.

16. A wiring board comprising an insulating layer having a depression on its surface and a conductive metal filled in the depression, wherein a depressed wiring pattern is formed from the conductive metal filled in the depression and is formed in such a manner that the sectional width of the depressed wiring pattern is decreased in the depth direction from the surface of the insulating layer.

17. The wiring board as claimed in claim 16, wherein on the back surface side of the insulating layer, a protruded wiring pattern made of a conductive metal is formed.

18. The wiring board as claimed in claim 16, having depressed wiring patterns of at least two depths, which differ in depth from the surface of the insulating layer.

19. The wiring board as claimed in claim 16, wherein a depression that passes through the insulating layer from the front surface side to the back surface side is formed, and the depression is filled with a conductive metal to form a via hole.

20. The wiring board as claimed in claim 19, wherein the back surface side tip of the via hole made of the conductive metal filled in the depression that passes through the insulating layer from the front surface side to the back surface side is connected to the protruded wiring pattern formed on the back surface side of the insulating layer.

21. The wiring board as claimed in claim 16, wherein the insulating layer is formed from a cured body of a curing resin that is cured by heat and/or light.

22. The wiring board as claimed in claim 18, wherein the depressed wiring pattern is formed by allowing a mold pattern, which is formed in such a manner that the sectional width of the lower end on the support base side is larger than the sectional width of the tip, to penetrate into an uncured curing resin, then curing the curing resin, depositing a conductive metal on the surface of the curing resin cured body where the depression has been formed, and polishing the deposited metal until the curing resin cured body is exposed.

23. A process for producing a wiring board, comprising:
allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into an uncured or semi-cured curing resin layer of a laminate having the curing resin layer on a surface of a support, to transfer the mold pattern,
curing the curing resin layer,
then releasing the laminate from the mold,
depositing a conductive metal on the surface of the thus released laminate, and
then polishing the deposited metal layer in such a manner that the surface of the curing resin cured body layer of the laminate is exposed, to form a depressed wiring pattern.

24. The process for producing a wiring board as claimed in claim 23, wherein after the laminate is released from the mold and before the conductive metal is deposited, the released laminate is subjected to desmearing treatment.

25. The process for producing a wiring board as claimed in claim 23, wherein the support constituting the laminate comprises a conductive metal, and a protruded wiring pattern is formed by forming a photosensitive resin layer on the surface of the support comprising the conductive metal, exposing and developing the photosensitive resin layer to form a pattern and selectively etching the conductive metal using the pattern as a masking material.

26. The process for producing a wiring board as claimed in claim 23, wherein the support base formed in the wiring board-forming mold is a light-transmitting base, and by pressing the mold pattern formed in the wiring board-forming mold onto an uncured photo-curing resin and exposing the photo-curing resin to light through the light-transmitting base, at least a part of the photo-curing resin is cured to transfer a given pattern corresponding to the mold pattern.

27. The process for producing a wiring hoard as claimed in claim 23, wherein the support base formed in the wiring board-forming mold is a light-transmitting base, and the light-transmitting base comprises quartz, a glass plate or a light-transmitting synthetic resin plate.

28. The process for producing a wiring board as claimed in claim 23, wherein the ratio (W1/W2) of the sectional width W1 of the support base side bottom of the mold pattern to the sectional width W2 of the top of the mold pattern in the same section of the mold pattern in the wiring board-forming mold is in the range of 1.01 to 2.0.

29. The process for producing a wiring board as claimed in claim 23, wherein on the support base surface of the wiring board-forming mold, mold patterns of at least two heights, which differ in height from the support base surface to the top, are formed.

30. The process for producing a wiring board as claimed in claim 23, wherein the mold pattern of the wiring board-forming mold is formed from a metal.

31. The process for producing a wiring board as claimed in claim 23, wherein the mold pattern of the wiring board-forming mold is formed by etching a metal layer formed on the surface of the support base.

32. A process for forming a via hole, comprising:
allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into an uncured or semi-cured curing resin layer of a laminate having the curing resin layer on a surface of a support, to transfer the mold pattern,
curing the curing resin layer,
then releasing the laminate from the mold,
depositing a conductive metal on the surface of the thus released laminate, and
then polishing the deposited metal layer in such a manner that the surface of the curing resin cured body layer of the laminate is exposed, to form a via hole that passes through the cured resin layer of the laminate.

33. The process for forming a via hole as claimed in claim 32, wherein after the laminate is released from the mold and before the conductive metal is deposited, the released laminate is subjected to desmearing treatment.

34. The process for forming a via hole as claimed in claim 32, wherein the support constituting the laminate comprises a conductive metal, and a protruded wiring pattern is formed by forming a photosensitive resin layer on the support comprising the conductive metal, exposing and developing the photosensitive resin layer to form a pattern and selectively etching the conductive metal using the pattern as a masking material.

35. A process for producing a multi-layer laminated wiring board, comprising carrying out, at least once, a step which comprises:
allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern to penetrate into an uncured or semi-cured curing resin layer of a laminate having the curing resin layer on a surface of a support comprising a conductive metal, to transfer the mold pattern,
curing the curing resin layer,
then releasing the laminate from the mold,
depositing a conductive metal on the surface of the thus released laminate,
then polishing the deposited metal layer in such a manner that the surface of the curing resin cured body layer of the laminate is exposed, to form a depressed wiring pattern and a via hole that passes through the cured resin layer Of the laminate, and further comprising, at least once,
forming an uncured or semi-cured curing resin layer on the curing resin cured body surface on which the depressed wiring pattern and the via hole have been formed,
allowing a wiring board-forming mold, which comprises a support base and a mold pattern that is formed in a protruded shape on one surface of the support base in such a manner that the sectional width of the mold pattern on the support base side is larger than the sectional width thereof on the tip side in the same section of the mold pattern, to penetrate into the curing resin layer, to transfer the mold pattern,
curing the curing resin layer,
then releasing the curing resin cured body from the mold,
depositing a conductive metal on the surface of the thus released cured resin layer laminate, and
then polishing the deposited metal layer in such a manner that the surface of the curing resin cured body layer of the laminate is exposed, to form a depressed wiring pattern and a via hole that passes through the cured resin layer of the laminate.

36. The process for producing a multi-layer laminated wiring board as claimed in claim 35, wherein after the cured resin is released from the mold and before the conductive metal is deposited, the released cured resin laminate is subjected to desmearing treatment.

37. The process for producing a multi-layer laminated wiring board as claimed in claim 35, wherein the support constituting the laminate comprises a conductive metal, and a protruded wiring pattern is formed by forming a photosensitive resin layer on the support comprising the conductive metal, exposing and developing the photosensitive resin layer to form a pattern and selectively etching the conductive metal using the pattern as a masking material.

38. A process for producing a wiring board, comprising bringing a precision mold having a mold pattern on a surface of a mold base into contact with a surface of a metal thin film formed on an organic insulating base, pressing the mold to form a depression having a shape corresponding to the mold pattern formed in the precision mold, said depression being formed in the depth direction of the organic insulating base from the metal thin film side, thereafter forming a metal plating layer having a thickness larger than the depth of the depression formed on the metal thin film to fill the plating metal in the depression formed by the precision mold, and then polishing the metal plating layer until the organic insulating base is exposed from the surface of the metal plating layer, to form a wiring pattern.

39. The process for producing a wiring board as claimed in claim 38, wherein the metal thin film has a thickness of 0.1 to 1 μm.

40. The process for producing a wiring board as claimed in claim 38, wherein the metal thin film has an elongation e of not less than 0.07.

41. The process for producing a wiring board as claimed in claim 39, wherein the metal thin film is formed by activating the surface of the organic insulating base and depositing copper in a thickness of 0.1 to 1 μm on the activated organic insulating base through electroless copper plating.

42. The process for producing a wiring board as claimed in claim 38, wherein the metal thin film is formed by laminating a copper foil onto the organic insulating base, then annealing the copper foil and subjecting the annealed copper foil to half etching to give a thickness of 0.1 to 1 μm.

43. The process for producing a wiring board as claimed in claim 38, wherein the metal thin film is formed by sputtering copper in a thickness of 0.1 to 1 μm on the organic insulating base.

44. The process for producing a wiring board as claimed in claim 38, wherein the metal thin film is formed by sputtering copper on the organic insulating base, then forming a Zn plating layer on the surface of the sputtering copper layer and then performing annealing to form a layer of an alloy of sputtering copper and Zn.

45. The process for producing a wiring board as claimed in claim 38, wherein the metal thin film is formed by sputtering a Zn—Al superplastic alloy on the surface of the organic insulating base.

46. The process for producing a wiring board as claimed in claim 38, wherein the organic insulating base comprises a liquid crystal polymer, all epoxy resin, a polymide or a cured or uncured laminated sizing agent.

47. The process for producing a wiring board as claimed in claim 38, wherein when the line width of a surface of a circuit formed by the precision mold is indicated by d (μm), the depth thereof is indicated by h (μm) and the elongation of the metal thin film at break is indicated by e, the metal thin film has a relationship represented by the following formula (I):
h<1/2×d×\sqrt{e×e+e} (1)

48. The process for producing a wiring board as claimed in claim 38, wherein on the metal thin film on the organic insulating base, an electroplating layer is formed in a thickness of 101 to 200% based on the depth h of the depression formed on the metal thin film.

49. The process for producing a wiring board as claimed in claim 38, wherein after the metal plating layer is polished until the organic insulating base is exposed from the surface of the metal plating layer to form a wiring pattern of the plating metal filled in the depression of the organic insulating base, a plating layer made of a metal different from the metal filled is formed on the surface of the thus formed wiring pattern.

50. A wiring board comprising a wiring pattern that is formed by filling a plating metal, through a metal thin film, in a depression formed in an organic insulating base.

51. The wiring board as claimed in claim 50, wherein the extensible metal thin film is formed by processing a copper foil.
